(19) United States
(12) Patent Application Publication
(10) Pub. No.: US 2023/0123987 A1
(43) Pub. Date: Apr. 20, 2023

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Jung-Chien CHENG, Tainan City (TW); Kuo-Cheng CHIANG, Zhubei City (TW); Shi-Ning JU, Hsinchu City (TW); Guan-Lin CHEN, Baoshan Township (TW); Chih-Hao WANG, Baoshan Township (TW)

(73) Assignee: Taiwan Semiconductor Manufacturing Company, Ltd., Hsinchu (TW)

(21) Appl. No.: 17/686,074

(22) Filed: Mar. 3, 2022

Related U.S. Application Data
(60) Provisional application No. 63/255,627, filed on Oct. 14, 2021.

(51) Int. Cl. H01L 29/06; H01L 29/423; H01L 29/786; H01L 29/66; H01L 21/8234

(52) U.S. Cl. CPC H01L 29/0665; H01L 21/823412; H01L 21/823418; H01L 29/42392; H01L 29/66553; H01L 29/66742; H01L 29/78618; H01L 29/78696

(57) ABSTRACT

A semiconductor device structure is provided. The semiconductor device structure includes a plurality of first nanostructures stacked over a substrate in a vertical direction. The semiconductor device structure includes a gate structure surrounding the first nanostructures, and an S/D structure adjacent to the gate structure. The semiconductor device structure also includes an inner spacer layer formed between the gate structure and the S/D structure, and a hard mask layer formed over the inner spacer layer. The hard mask layer is between the gate structure and the S/D structure, and is in direct contact with the inner spacer layer.

### CROSS REFERENCE TO RELATED APPLICATIONS

This Application claims the benefit of U.S. Provisional Application No. 63/255,627 filed on Oct. 14, 2021, the entirety of which is incorporated by reference herein.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

As the semiconductor industry has progressed into nanometer technology process nodes in pursuit of higher device density, higher performance, and lower costs, challenges from both fabrication and design issues have resulted in the development of three-dimensional designs.

Although existing semiconductor devices have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 shows a top view of a semiconductor structure, in accordance with some embodiments.

FIGS. 2A to 2J illustrate perspective views of intermediate stages of manufacturing a semiconductor structure in accordance with some embodiments.

FIGS. 3A-1 3A-2 3B-1 3B-2 3C-1 3D-1 3D-2 3E-1 3E-2 3F-1 3F-2 3G-1 3G-2 3H-1 3H-2 3I-1 3I-2 3I-3 3J-1 3J-2 3J-3 3L-1 3L-2 3L-3 3M-1 3M-2 3N-1 3N-2 3N-3 3O-1 show cross-sectional representations of various stages of forming the semiconductor device structure along line X-X′ shown in FIG. 2J, in accordance with some embodiments of the disclosure.

FIGS. 3A-2 3B-1 3B-2 3C-1 3D-1 3D-2 3E-1 3E-2 show cross-sectional representations of various stages of forming the semiconductor device structure along line Y-Y′ shown in FIG. 2J, in accordance with some embodiments of the disclosure.

FIGS. 3F-1 3F-2 3G-1 3G-2 3H-1 3H-2 3I-1 3I-2 3I-3 3J-1 3J-2 3J-3 3L-1 3L-2 3L-3 3M-1 3M-2 3N-1 3N-2 3N-3 3O-1 3O-2 show cross-sectional representations of various stages of forming the semiconductor device structure along line Y₂-Y₂′ shown in FIG. 2J, in accordance with some embodiments of the disclosure.

FIG. 3B'-1 shows a cross-sectional representation of forming the notches of a semiconductor device structure, in accordance with some embodiments of the disclosure.

FIG. 3C'-1 shows a cross-sectional representation of forming the inner spacers of the semiconductor device structure, in accordance with some embodiments of the disclosure.

FIG. 3I-3 shows an enlarged cross-sectional representation of the region A in FIG. 3I-2, in accordance with some embodiments of the disclosure.

FIGS. 3J-3 3L-1 3L-2 3L-3 3M-1 3M-2 3N-1 3N-2 3N-3 3O-1 3O-2 3O-3 show enlarged cross-sectional representation of the region B in FIGS. 3J-1 3J-2 3J-3 3L-1 3L-2 3L-3 3M-1 3M-2 3N-1 3N-2 3N-3 3O-1, in accordance with some embodiments of the disclosure.

FIG. 3O-4 shows an enlarged cross-sectional representation of the region A in FIG. 3O-2, in accordance with some embodiments of the disclosure.

FIG. 3O-1 shows a cross-sectional representation of forming the metal layer 194 of the semiconductor device structure, in accordance with some embodiments of the disclosure.

FIG. 4 shows a cross-sectional representation of a semiconductor device structure, in accordance with some embodiments.

FIG. 5 shows a cross-sectional representation of a semiconductor device structure, in accordance with some embodiments.

FIGS. 6A-1 6A-2 6B-1 6B-2 6C-1 6C-2 6D-1 show cross-sectional representations of various stages of forming the semiconductor device structure along line X-X′ shown in FIG. 2J, in accordance with some embodiments of the disclosure.

FIGS. 6A-2 6B-1 6B-2 6C-1 6C-2 6D-1 6D-2 show enlarged cross-sectional representation of the region B in FIGS. 6A-1 6A-2 6B-1 6B-2 6C-1 6C-2 6D-1, in accordance with some embodiments of the disclosure.

FIG. 7 shows a cross-sectional representation of a semiconductor device structure, in accordance with some embodiments.

FIG. 8 shows a cross-sectional representation of a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments for forming a semiconductor device structure are provided. The semiconductor device structure includes a fin structure over a substrate, and the fin structure includes a number of nanostructures. A gate structure wraps around the nanostructures. A hard mask layer is formed over the fin structure to protect the underlying layers from being etched by an etching process. A portion of the hard mask layer is removed, but another portion of the hard mask layer is remaining. The hard mask layer is between an inner spacer layer and a gate spacer layer. In addition, the hard mask layer is between the gate structure and an S/D structure.

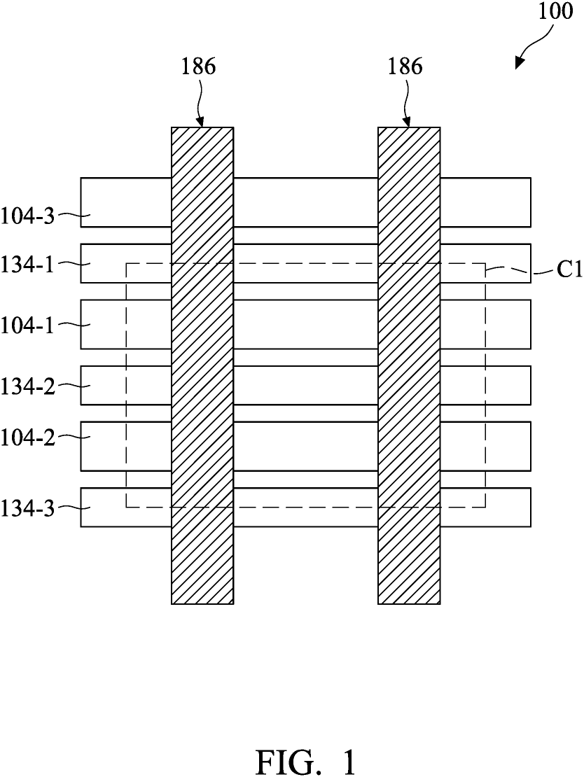

FIG. 1 shows a top view of a semiconductor structure 100, in accordance with some embodiments. FIG. 1 has been simplified for the sake of clarity to better understand the inventive concepts of the present disclosure. Additional features may be added in the semiconductor structure 100, and some of the features described below may be replaced, modified, or eliminated.

As shown in FIG. 1, the fin structures 104-1, 104-2, 104-3 are formed over a substrate. The dielectric features 134-1, 134-2, 134-3 are formed between two adjacent fin structures 104-1, 104-2, 104-3.

The semiconductor structure 100 may include multi-gate devices and may be included in a microprocessor, a memory, or other IC devices. For example, the semiconductor structure 100 may be a portion of an IC chip that include various passive and active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other applicable components, or combinations thereof.

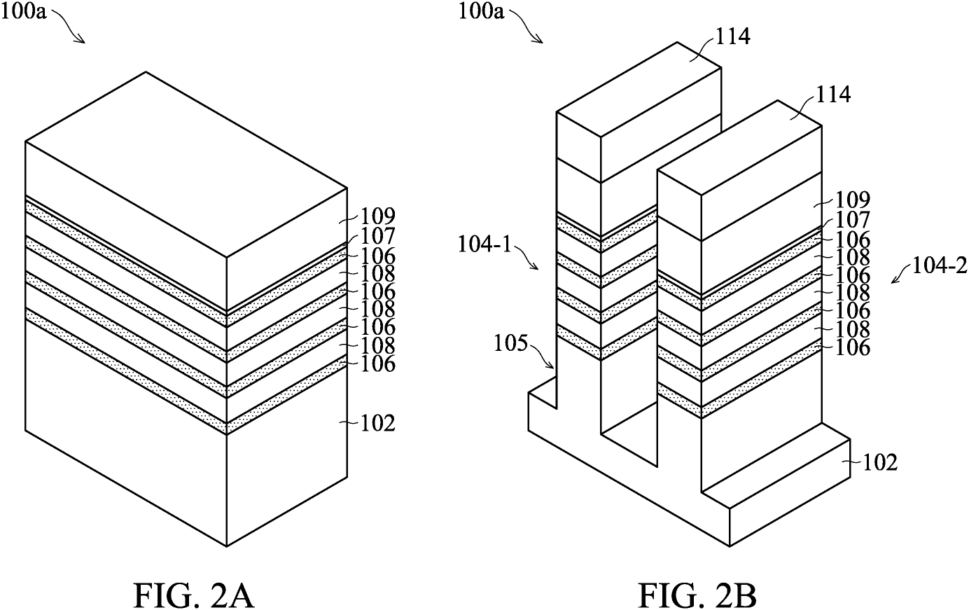

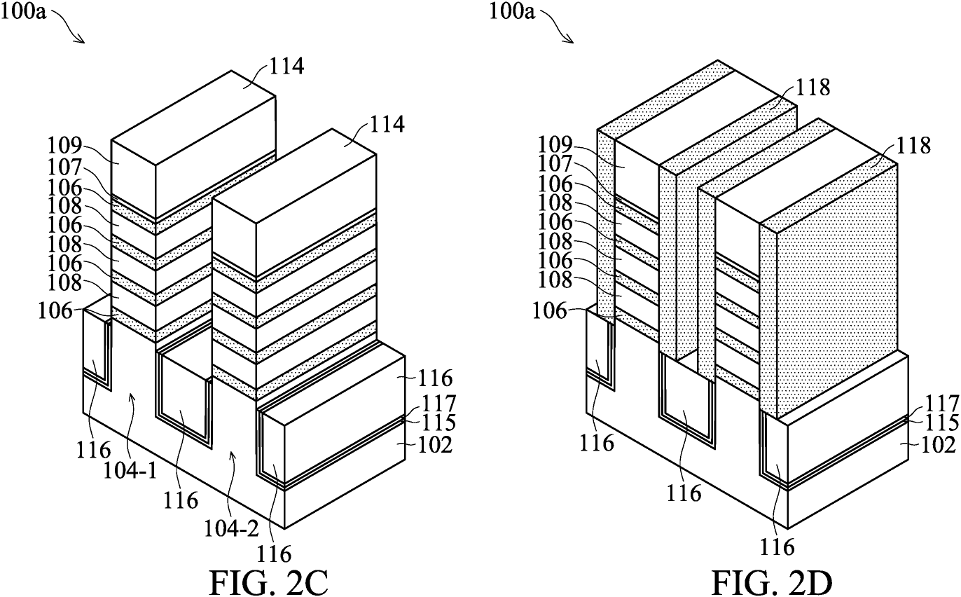

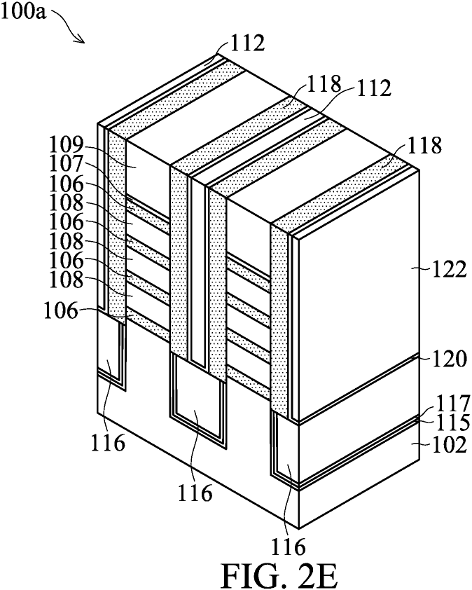

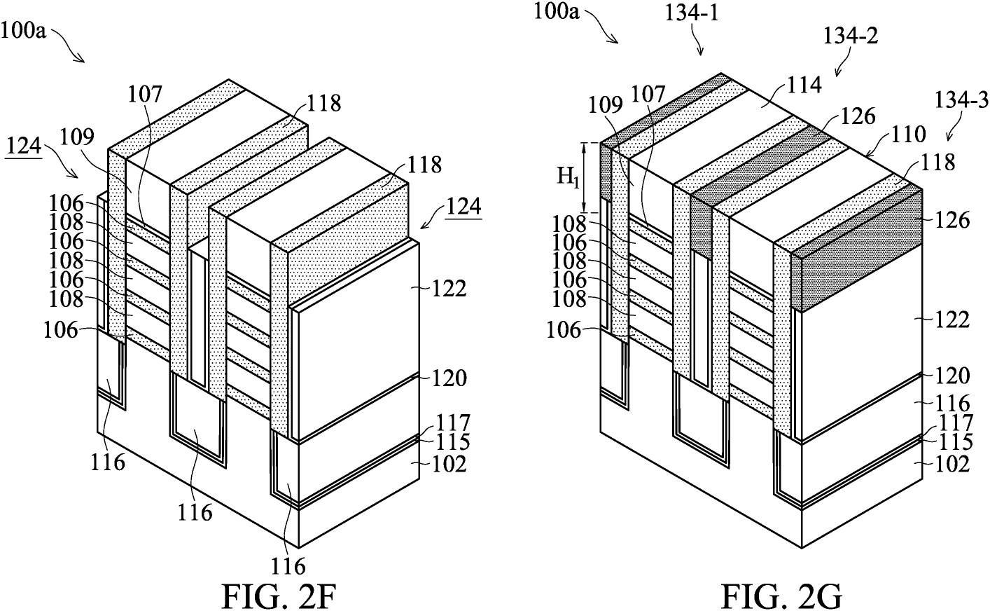

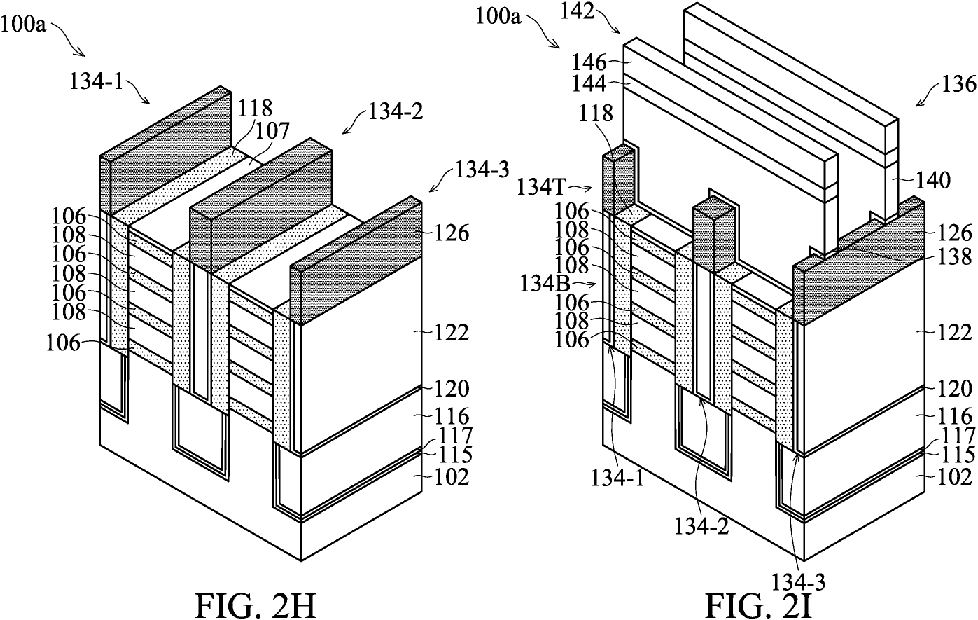

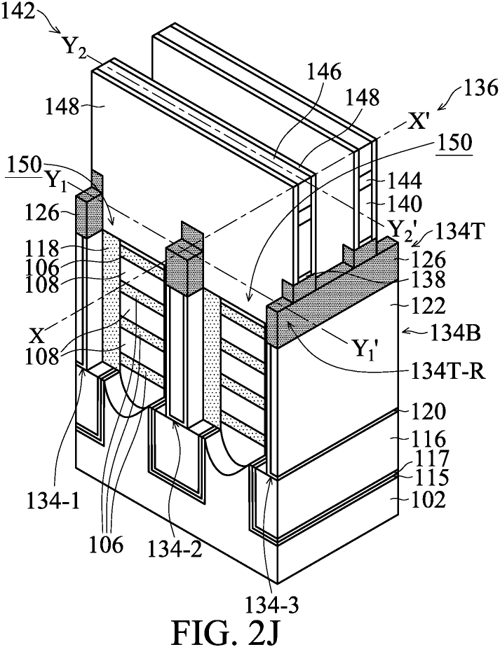

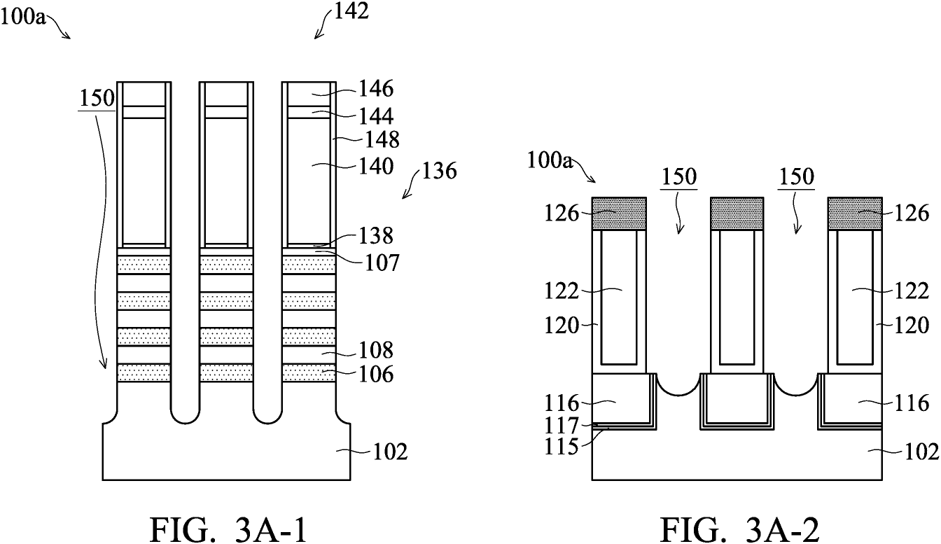

FIGS. 2A to 2J illustrate perspective views of intermediate stages of manufacturing a semiconductor structure 100a in accordance with some embodiments. More specifically, FIGS. 2A to 2J illustrate diagrammatic perspective views of intermediate stages of manufacturing the semiconductor structure 100a shown in the dotted line block C₁ of FIG. 1.

As shown in FIG. 2A, a substrate 102 is provided. The substrate 102 may be made of silicon or other semiconductor materials. Alternatively or additionally, the substrate 102 may include other elementary semiconductor materials such as germanium. In some embodiments, the substrate 102 is made of a compound semiconductor such as silicon carbide, gallium arsenic, indium arsenide, or indium phosphide. In some embodiments, the substrate 102 is made of an alloy semiconductor such as silicon germanium, silicon germanium carbide, gallium arsenic phosphide, or gallium indium phosphide. In some embodiments, the substrate 102 includes an epitaxial layer. For example, the substrate 102 has an epitaxial layer overlying a bulk semiconductor.

A number of first semiconductor layers 106 and a number of second semiconductor layers 108 are sequentially alternately formed over the substrate 102. Next, a hard mask layer 107 is formed over the topmost first semiconductor layer 106, and a dummy layer 109 is formed over the hard mask layer 107. The first semiconductor layers 106 and the second semiconductor layers 108 are vertically stacked to form a stacked nanostructures structure (or a stacked nanosheet or a stacked nanowire). Note that the topmost layer is the first semiconductor layer 106. The number of the first semiconductor layers 106 is four, and the number of the second semiconductor layers 108 is three. The number of the first semiconductor layers 106 is greater than the first semiconductor layers 106 to make the topmost layer is second semiconductor layer 108. When the topmost layer is first semiconductor layer 106, the second semiconductor layer 108 (used as nanostructure) can be protected by other layers (such as the inner spacer layer 156 and the hard mask layer 107).

In some embodiments, the first semiconductor layers 106 and the second semiconductor layers 108 independently include silicon (Si), germanium (Ge), silicon germanium (Si₁₋ₓGex, 0.1 <x<0.7, the value x is the atomic percentage of germanium (Ge) in the silicon germanium), indium arsenide (InAs), indium gallium arsenide (InGaAs), indium antimonide (InSb), or another applicable material. In some embodiments, the first semiconductor layer 106 and the second semiconductor layer 108 are made of different materials.

The first semiconductor layers 106 and the second semiconductor layers 108 are made of different materials having different lattice constant. In some embodiments, the first semiconductor layer 106 is made of silicon germanium (Si₁₋ₓGex, 0.1 <x<0.7), and the second semiconductor layer 108 is made of silicon (Si). In some other embodiments, the first semiconductor layer 106 is made of silicon (Si), and the second semiconductor layer 108 is made of silicon germanium (Si₁₋ₓGex, 0.1 <x<0.7).

The hard mask layer 107 may be made of silicon oxide (SiO), silicon nitride (SiN), silicon carbonitride (SiCN), silicon oxynitride (SiON), or other applicable materials. The hard mask layer 107 is made of the material having Young’s modulus in a range from about 130 Gpa to about 250 GPa. When the Young’s modulus of the hard mask layer 107 is within the above-mentioned range, the material of the hard mask layer 107 can have enough etching resistance to protect the underlying layers from being damaged.

The dummy layer 109 may be made of silicon (Si), silicon germanium or applicable material. In some embodiments, the first semiconductor layers 106, the second semiconductor layers 108 and the dummy layer 109 are formed by a selective epitaxial growth (SEG) process, a chemical vapor deposition (CVD) process (e.g. low-pressure CVD (LPCVD), plasma enhanced CVD (PECVD)), a molecular epitaxy process, or another applicable process. In some embodiments, the first semiconductor layers 106, the second semiconductor layers 108 and the dummy layer 109 are formed in-situ in the same chamber.

In some embodiments, the hard mask layer 107 is formed by a deposition processes, such as a CVD process, HDPCVD process, spin-on process, sputtering process, and/or combinations thereof.

In some embodiments, the thickness of each of the first semiconductor layers 106 is in a range from about 1.5 nanometers (nm) to about 20 nm. Terms such as “about” in conjunction with a specific distance or size are to be interpreted as not to exclude insignificant deviation from the specified distance or size and may include for example deviations of up to 20%. In some embodiments, the first semiconductor layers 106 are substantially uniform in thickness. In some embodiments, the thickness of each of the second semiconductor layers 108 is in a range from about 1.5 nm to about 20 nm. In some embodiments, the second semiconductor layers 108 are substantially uniform in thickness.

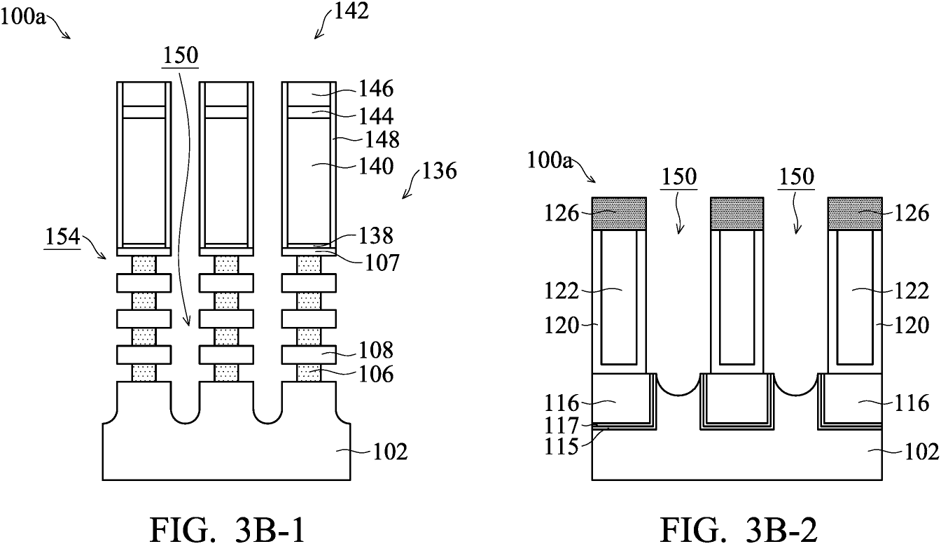

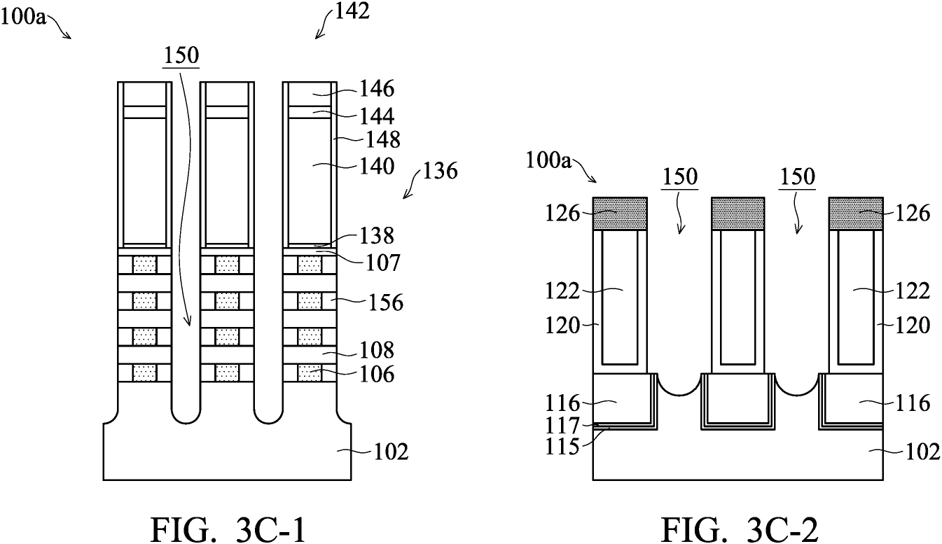

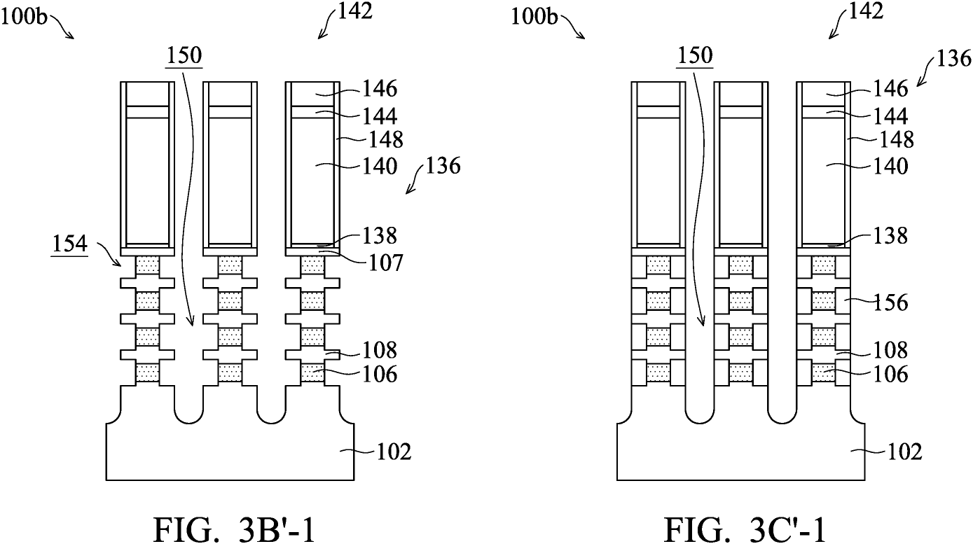

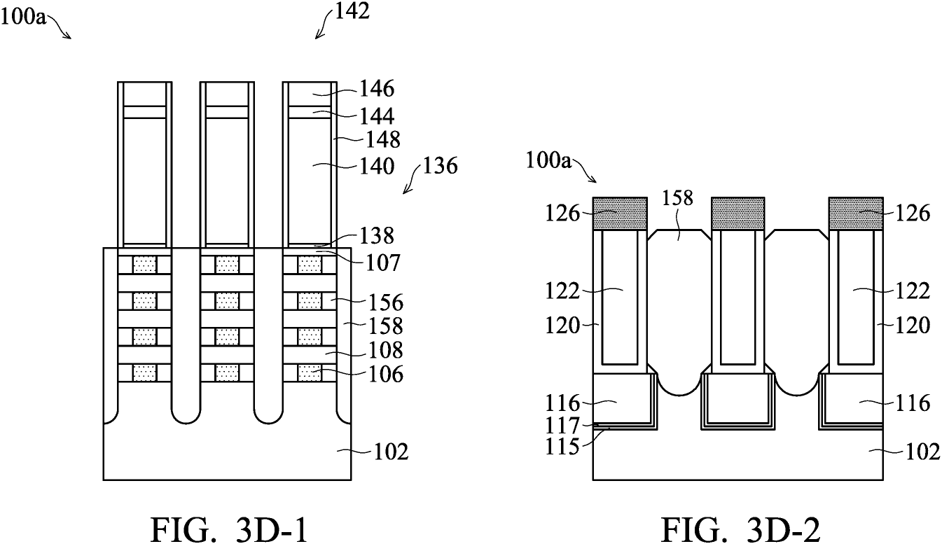

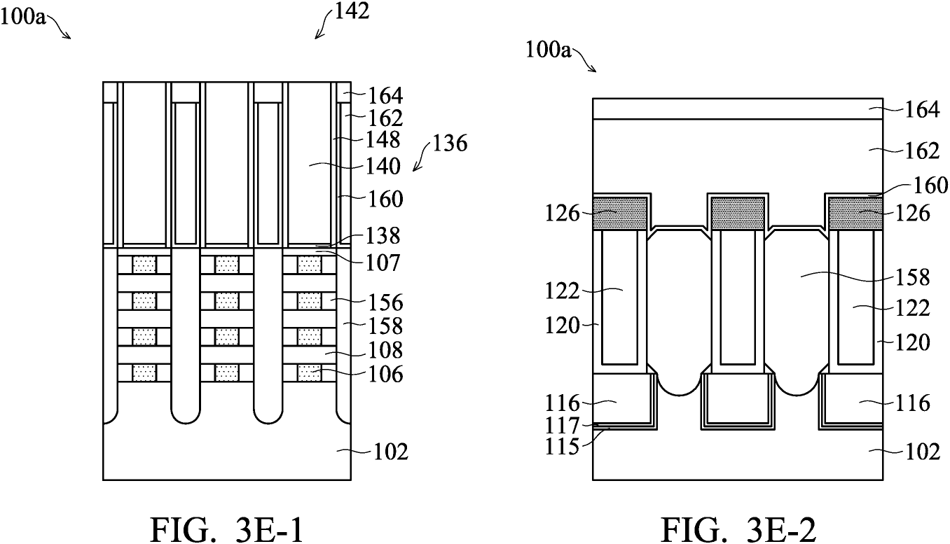

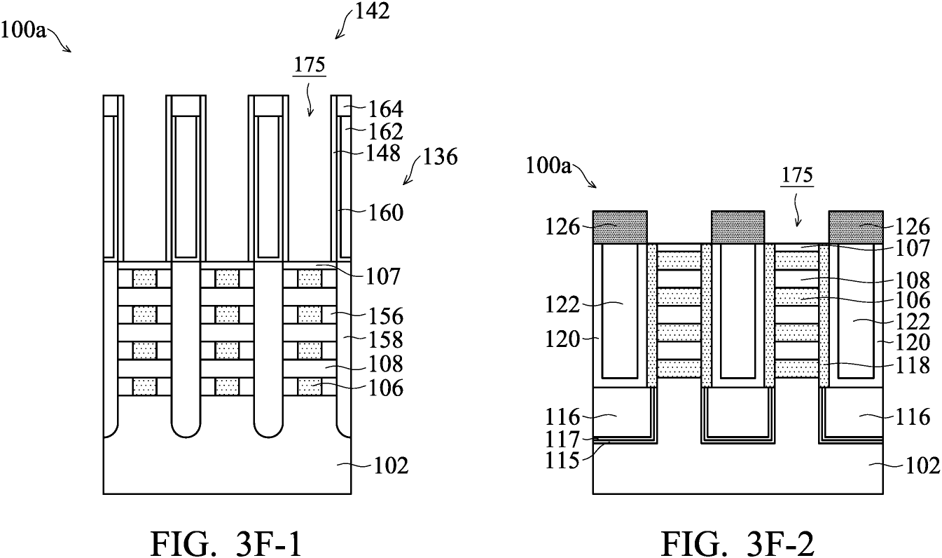

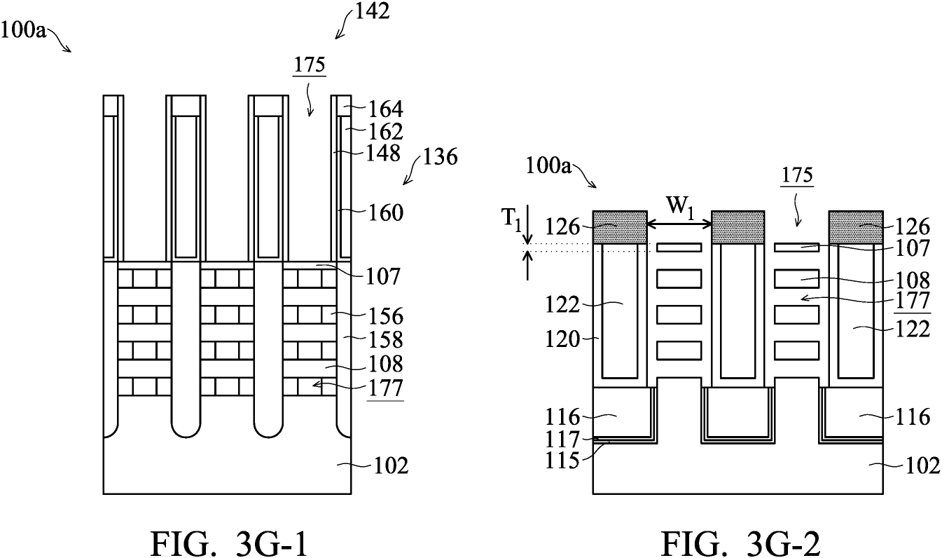

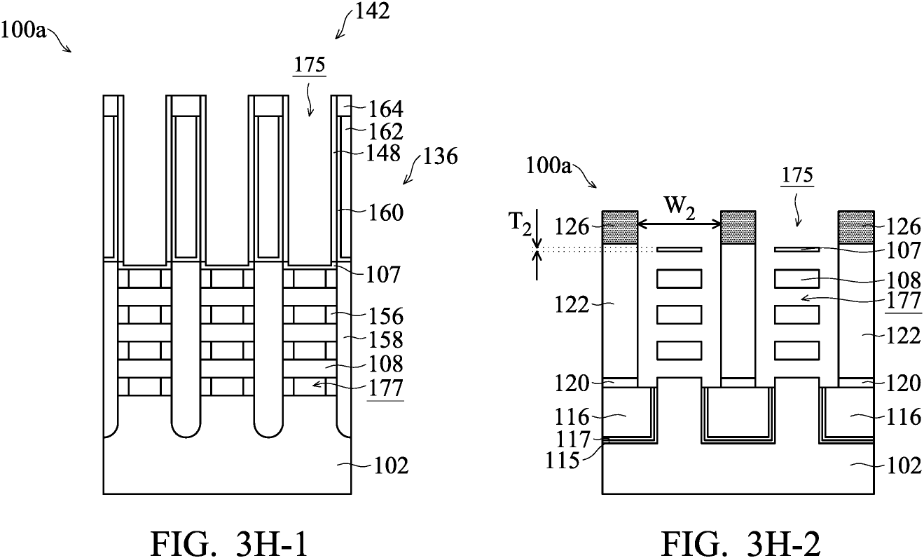

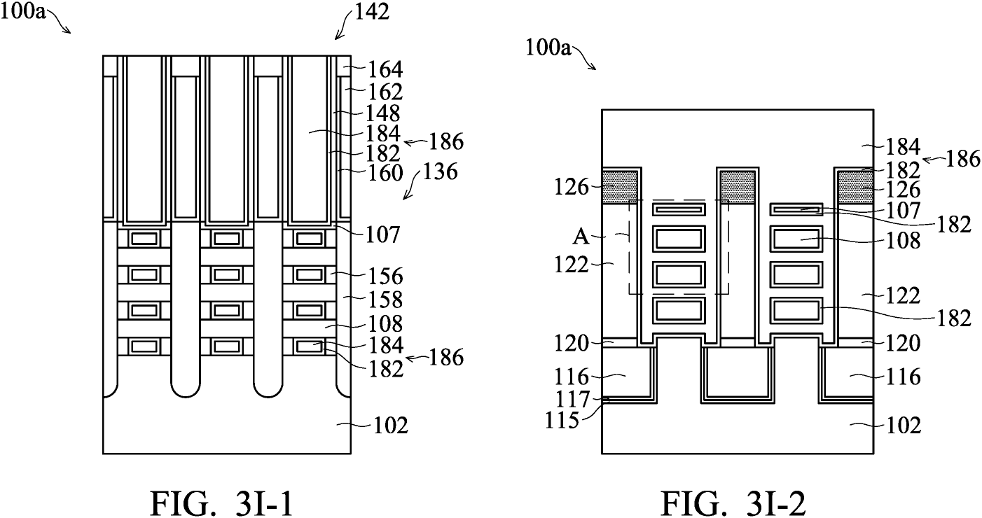

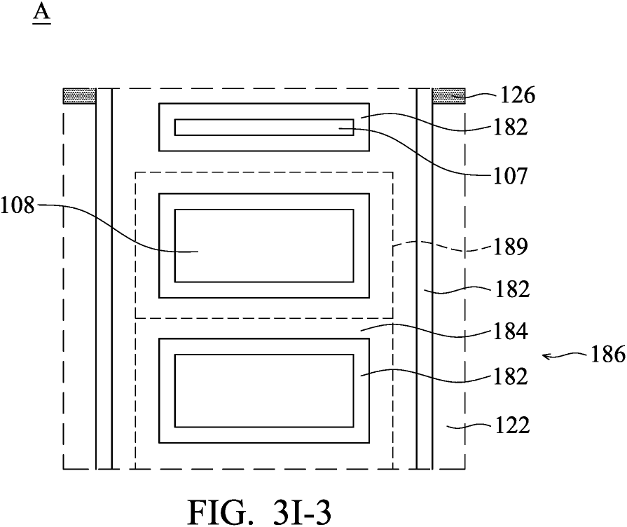

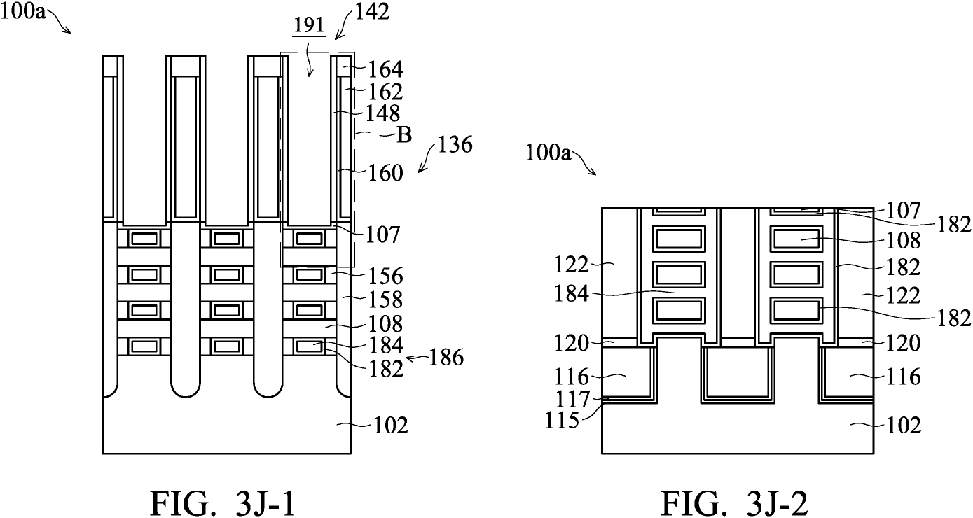

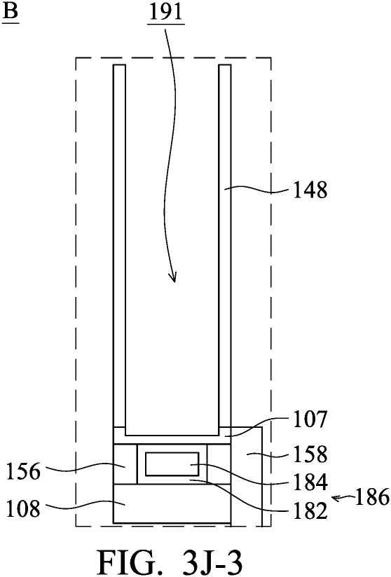

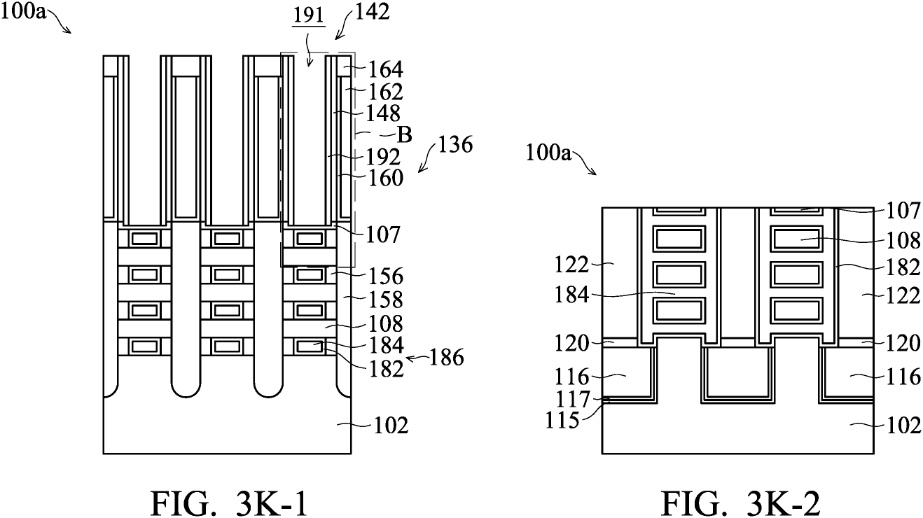

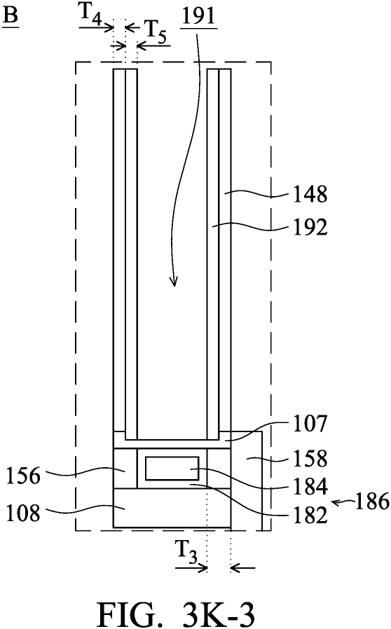

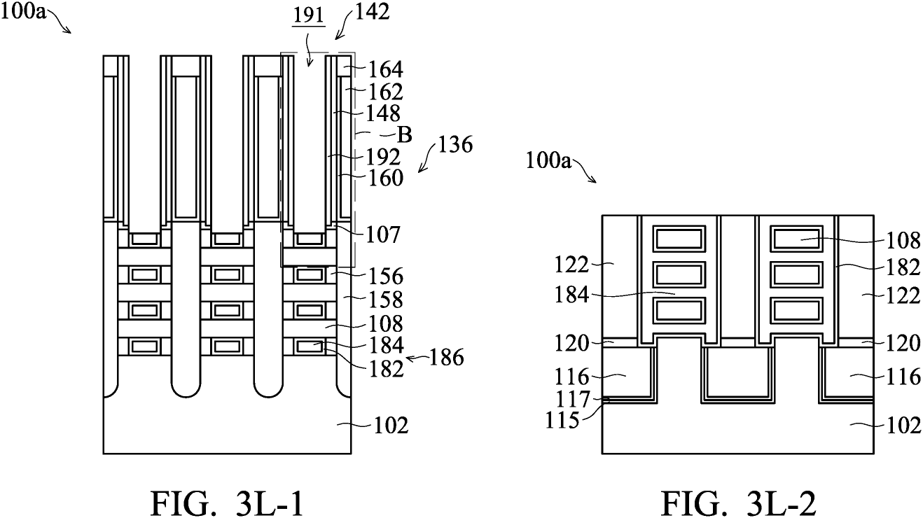

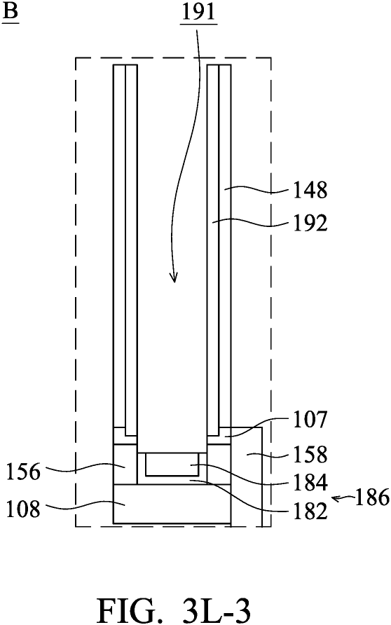

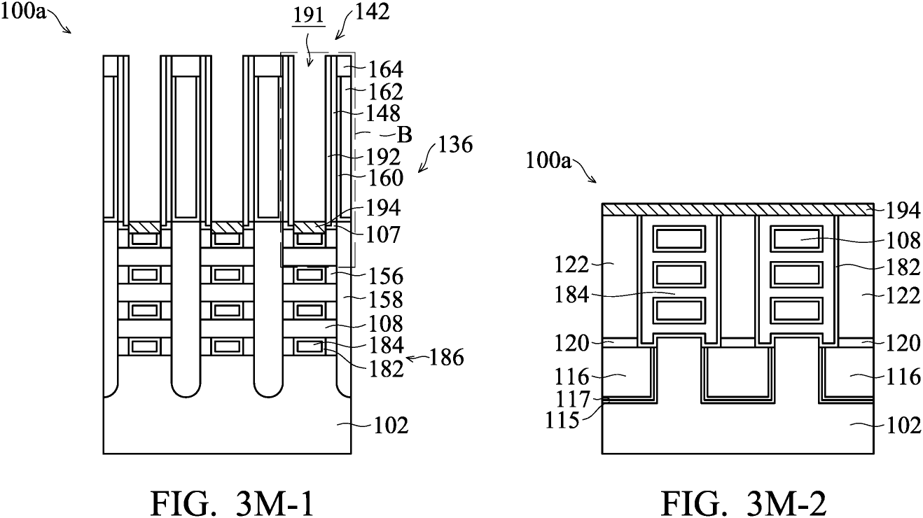

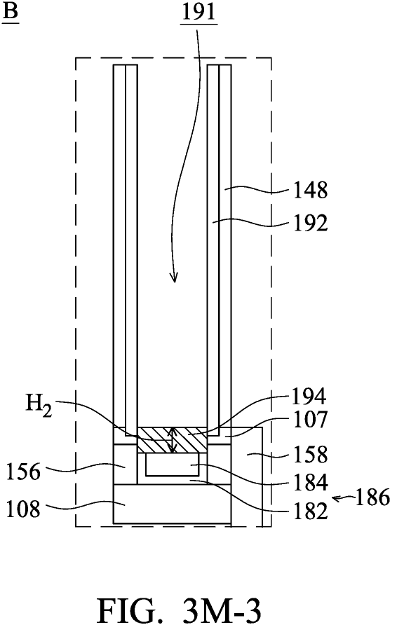

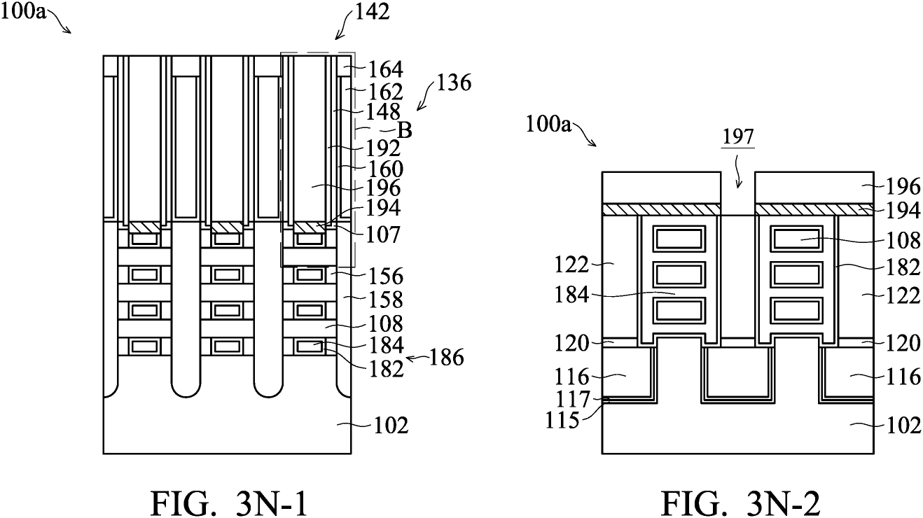

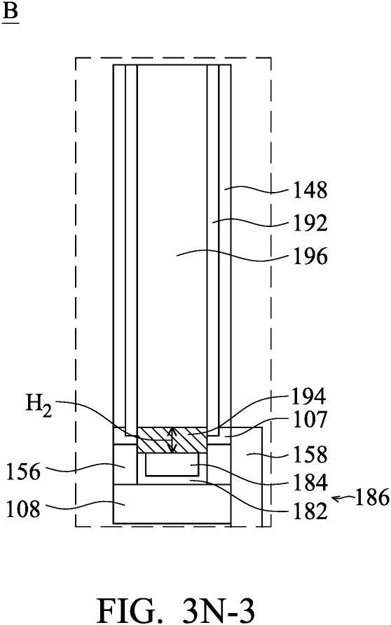

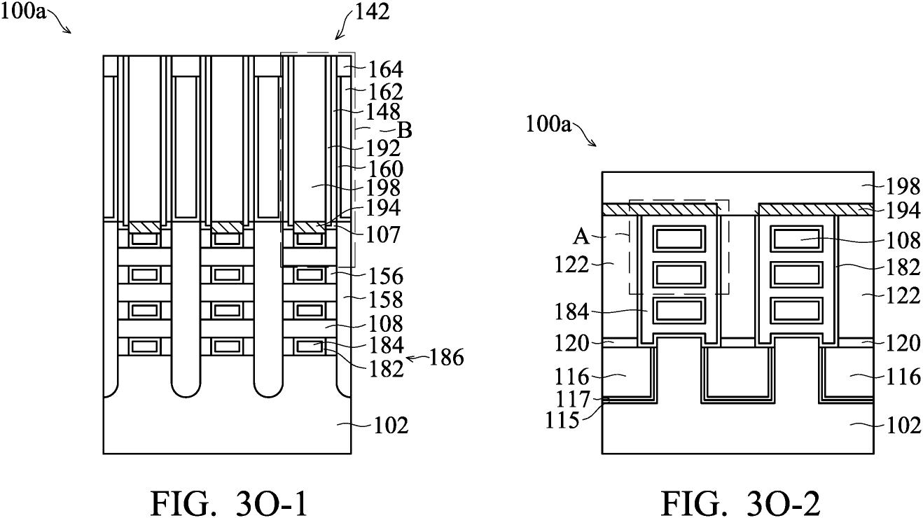

In some embodiments, the thickness of the hard mask layer 107 is in a range from about 2 nanometers (nm) to about 20 nm. If the thickness of the hard mask layer 107 is smaller than 2 nm, the hard mask layer 107 may be bent easily. If the thickness of the hard mask layer 107 is greater than 2 nm, the formation of the gate dielectric layer 182 or the gate electrode layer 184 into the gaps 177 (formed later, as shown in FIG. 3G-1) may become difficulty.

In some embodiments, the thickness of the dummy layer 109 is greater than that of the first semiconductor layers 106 or that of the second semiconductor layers 108. In some embodiments, the thickness of the dummy layer 109 is in a range from about 15 nanometers (nm) to about 40 nm. The thickness of the cap layer 126 (formed later) determines by the thickness of the dummy layer 109. If the cap layer 126 is not thick enough, it cannot protect the underlying layers (the liner layer 120 and the filling layer 122). If the liner layer 120 and the filling layer 122 are etched, the unwanted bridge between two adjacent S/D structures may occur.

Then, as shown in FIG. 2B, the first semiconductor layers 106, the second semiconductor layers 108, the hard mask layer 107 and the dummy layer 109 are patterned to form fin structures 104-1 and 104-2, in accordance with some embodiments of the disclosure. In some embodiments, the fin structures 104-1 and 104-2 include base fin structures 105 and the semiconductor material stacks, including the first semiconductor layers 106, the second semiconductor layers 108, the hard mask layer 107 and the dummy layer 109, formed over the base fin structure 105.

In some embodiments, the patterning process includes forming mask structure 114 over the semiconductor material stack, and etching the semiconductor material stack and the underlying substrate 102 through the mask structure 114. In some embodiments, the mask structure 114 is a multilayer structure including a pad oxide layer and a nitride layer formed over the pad oxide layer. The pad oxide layer may be made of silicon oxide, which may be formed by thermal oxidation or CVD, and the nitride layer may be made of silicon nitride, which may be formed by CVD, such as LPCVD or plasma-enhanced CVD (PECVD).

Afterwards, as shown in FIG. 2C, a liner 115 and a liner 117 are formed to cover the fin structures 104-1 and 104-2, in accordance with some embodiments of the disclosure. In some embodiments, the liners 115 and 117 are made of different dielectric materials. In some embodiments, the liner 115 is made of oxide and the liner 117 is made of nitride. In some embodiments, the liner 115 is omitted.

Next, an insulating material is formed around the fin structures 104-1 and 104-2 over the liner 117, and then the insulating material and the liners 115 and 117 are recessed to form an isolation structure 116, in accordance with some embodiments. The isolation structure 116 is configured to electrically isolate active regions (e.g. the fin structures 104-1 and 104-2) of the semiconductor structure and is also referred to as shallow trench isolation (STI) feature in accordance with some embodiments. In some embodiments, the insulating material is made of silicon oxide, silicon nitride, silicon oxynitride (SiON), another suitable insulating material, or a combination thereof.

Afterwards, as shown in FIG. 2D, after the isolation structure 116 is formed, cladding layers 118 are formed over the top surfaces and the sidewalls of the fin structures 104-1 and 104-2 over the isolation structure 116, in accordance with some embodiments. In some embodiments, the cladding layers 118 are made of semiconductor materials. In some embodiments, the cladding layers 118 are made of silicon germanium (SiGe). In some embodiments, the cladding layers 118 and the first semiconductor layers 106 are made of the same semiconductor material.

The cladding layer 118 may be formed by performing an epitaxy process, such as VPE and/or UHV CVD, molecular beam epitaxy, other applicable epitaxial growth processes, or combinations thereof. After the cladding layers 118 are deposited, an etching process may be performed to remove the portion of the cladding layer 118 not formed on the sidewalls of the fin structures 104-1 and 104-2, for example, using a plasma dry etching process. In some embodiments, the portions of the cladding layers 118 formed on the top surface of the fin structures 104-1 and 104-2 are partially or completely removed by the etching process, such that the thickness of the cladding layer 118 over the top surface of the fin structures 104-1 and 104-2 is thinner than the thickness of the cladding layer 118 on the sidewalls of the fin structures 104-1 and 104-2.

Before the cladding layers 118 are formed, a semiconductor liner (not shown) may be formed over the fin structures 104-1 and 104-2. The semiconductor liner may be a Si layer and may be incorporated into the cladding layers 118 during the epitaxial growth process for forming the cladding layers 118.

Next, as shown in FIG. 2E, a liner layer 120 and a filling layer 122 are sequentially formed over the cladding layers 118 and the isolation structure 116, in accordance with some embodiments. After the liner layer 120 is formed, the filling layer 122 is formed over the liner layer 120 to completely fill the spaces between the adjacent fin structures 104-1 and 104-2, and a polishing process is performed until the top surface of the dummy layer 109 are exposed. As a result, the top surface of the dummy layer 109 is substantially level with the top surface of the liner layer 120 and the top surface of the filling layer 122.

In some embodiments, the liner layer 120 is made of a low k dielectric material having a k value lower than 7. In some embodiments, the liner layer 120 is made of SiN, SiCN, SiOCN, SiON, or the like. The liner layer 120 may be deposited using CVD, PVD, ALD, HDPCVD, MOCVD, RPCVD, PECVD, LPCVD, ALCVD, APCVD, other applicable methods, or combinations thereof. In some embodiments, the liner layer 120 has a thickness in a range from about 2 nm to about 8 nm.

In some embodiments, the filling layer 122 and the liner layer 120 are both made of oxide but are formed by different methods. In some embodiments, the filling layer 122 is made of SiN, SiCN, SiOCN, SiON, or the like. The filling layer 122 may be deposited using a flowable CVD (FCVD) process that includes, for example, depositing a flowable material (such as a liquid compound) and converting the flowable material to a solid material by a suitable technique, such as thermal annealing and/or ultraviolet radiation treating.

Next, as shown in FIG. 2F, a portion of the filling layer 122 and a portion of the liner layer 120 are recessed to form recesses 124 by performing an etching process. In some embodiments, the filling layer 122 are formed using a flowable CVD process, so that the resulting filling layer 122 can have a relatively flat top surface after the etching process is performed.

Afterwards, as shown in FIG. 2G, a cap layer 126 is formed in the recesses 124, thereby forming dielectric features 134-1, 134-2, 134-3, in accordance with some embodiments. In some embodiments, the dielectric features 134-1, 134-2, and 134-3 are at opposite sides of the fin structures 104-1 and 104-2. The cap layer 126 is used to as a barrier to prevent adjacent S/D structures 158 (formed later) being bridged.

In some embodiments, the cap layer 126 is made of a high k dielectric material, such as HfO₂, ZrO₂, HfAlOₓ, HfSiOₓ, Al₂O₃, or the like. The dielectric materials for forming the cap layer 126 may be formed by performing ALD, CVD, PVD, oxidation-based deposition process, other suitable process, or combinations thereof. After the cap layers 126 are formed, a CMP process is performed until the dummy layer 109 is exposed in accordance with some embodiments. In some embodiments, the cap layer 126 has a first height H₁ in a range of about 5 nm to about 30 nm. The cap layers 126 should be thick enough to protect the lining layer 120 and the filling layer 122 during the subsequent etching processes, so that the dielectric features may be used to separate the adjacent source/drain structures formed afterwards.

Next, as shown in FIG. 2H, the dummy layer 109 over the fin structures 104-1 and 104-2 and the top portions of the cladding layers 118 are removed to expose the top surfaces of the hard mask layer 107, in accordance with some embodiments. In some embodiments, the top surfaces of the cladding layers 118 are substantially level with the top surface of the hard mask layer 107.

The dummy layer 109 and the cladding layers 118 may be recessed by performing one or more etching processes that have higher etching rate to the dummy layer 109 and the cladding layers 118 than the dielectric features 134-1, 134-2, 134-3, such that the dielectric features 134 are only slightly etched during the etching processes. The selective etching processes can be dry etching, wet drying, reactive ion etching, or other applicable etching methods.

Afterwards, as shown in FIG. 2I, dummy gate structures 136 are formed across the fin structure 104-1 and 104-2 and the dielectric features 134, in accordance with some embodiments. The dummy gate structures 136 may be used to define the source/drain regions and the channel regions of the resulting semiconductor structure 100.

In some embodiments, the dummy gate structure 136 includes a dummy gate dielectric layer 138 and a dummy gate electrode layer 140. In some embodiments, the dummy gate dielectric layer 138 is made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layer 138 is formed using thermal oxidation, CVD, ALD, physical vapor deposition (PVD), another suitable method, or a combination thereof.

In some embodiments, the dummy gate electrode layer 140 is made of conductive material includes polycrystalline-silicon (poly-Si), poly-crystalline silicon-germanium (poly-SiGe), or a combination thereof. In some embodiments, the dummy gate electrode layer 140 is formed using CVD, PVD, or a combination thereof.

In some embodiments, hard mask layers 142 are formed over the dummy gate structures 136. In some embodiments, the hard mask layers 142 include multiple layers, such as an oxide layer 144 and a nitride layer 146. In some embodiments, the oxide layer 144 is silicon oxide, and the nitride layer 146 is silicon nitride.

The formation of the dummy gate structures 136 may include conformally forming a dielectric material as the dummy gate dielectric layers 138. Afterwards, a conductive material may be formed over the dielectric material as the dummy gate electrode layers 140, and the hard mask layer 142 may be formed over the conductive material. Next, the dielectric material and the conductive material may be patterned through the hard mask layer 142 to form the dummy gate structures 136.

In some embodiments, the dielectric features 134-1, 134-2, 134-3 include a bottom portion 134B and a top portion 134T over the bottom portion 134B. The bottom portion 134B includes the liner layer 120 and the filling layer 122, and the top portion 134T includes the cap layer 126. The cap layer 126 may be configured to protect the dielectric features 134-1, 134-2, 134-3 during the subsequent etching processes.

Since the dielectric features 134-1, 134-2, 134-3 are self-aligned to the spaces between the fin structures 104-1 and 104-2, complicated alignment processes are not required when forming the dielectric features 134-1, 134-2, 134-3. In addition, the width of the dielectric features 134-1, 134-2, 134-3 may be determined by the widths of the spaces between the fin structures 104-1 and 104-2 and the thicknesses of the cladding layer 118. In some embodiments, the dielectric features 134-1, 134-2, 134-3 have substantially the same width. Meanwhile, in some embodiments, the spaces between the fin structures 104-1 and 104-2 have different widths, and the dielectric features 134 also have different widths. As shown in FIG. 1, the dielectric features 134-1, 134-2, 134-3 are formed between the fin structures 104-1 and 104-2 and are substantially parallel to the fin structures 104-1 and 104-2 in accordance with some embodiments.

Afterwards, as shown in FIG. 2J, after the dummy gate structures 136 are formed, first gate spacers 148 are formed along and covering opposite sidewalls of the dummy gate structure 136, in accordance with some embodiments. In some embodiments, the first gate spacers 148 also cover some portions of the top surfaces and the sidewalls of the dielectric features 134. The first gate spacers 148 are formed over the hard mask layer 107.

Afterwards, source/drain (S/D) recesses 150 are formed adjacent to the first gate spacers 148. More specifically, the fin structures 104-1 and 104-2 and the cladding layers 118 not covered by the dummy gate structures 136 and the first gate spacers 148 are recessed. In addition, in some embodiments, the top portions 134T of the dielectric features 134 are also recessed to have recessed portions 134T_R at the source/drain regions in accordance with some embodiments. In some other embodiments, the cap layers 126 are completely removed.

The first gate spacers 148 may be configured to separate source/drain structures 158 (formed afterwards, as shown in FIG. 3D-1) from the dummy gate structure 136. In some embodiments, the first gate spacers 148 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof.

In some embodiments, the fin structures 104-1 and 104-2 and the cladding layers 118 are recessed by performing an etching process. The etching process may be an anisotropic etching process, such as dry plasma etching, and the dummy gate structure 136 and the first gate spacers 148 may be used as etching masks during the etching process.

FIGS. 3A-1 3A-2 3B-1 3B-2 3C-1 3D-1 3D-2 3E-1 3E-2 3F-1 3F-2 3G-1 3G-2 3H-1 3H-2 3I-1 3I-2 3I-3 3J-1 3J-2 3J-3 3L-1 3L-2 3L-3 3M-1 3M-2 3N-1 3N-2 3N-3 3O-1 show cross-sectional representations of various stages of forming the semiconductor device structure 100a along line X-X′ shown in FIG. 2J, in accordance with some embodiments of the disclosure. FIGS. 3A-2 3B-1 3B-2 3C-1 3D-1 3D-2 3E-1 3E-2 show cross-sectional representations of various stages of forming the semiconductor device structure 100a along line Y₁-Y₁′ shown in FIG. 2J, in accordance with some embodiments of the disclosure. FIGS. 3F-1 3F-2 3G-1 3G-2 3H-1 3H-2 3I-1 3I-2 3I-3 3J-1 3J-2 3J-3 3L-1 3L-2 3L-3 3M-1 3M-2 3N-1 3N-2 3N-3 3O-1 3O-2 show cross-sectional representations of various stages of forming the semiconductor device structure 100a along line Y₂-Y₂′ shown in FIG. 2J, in accordance with some embodiments of the disclosure.

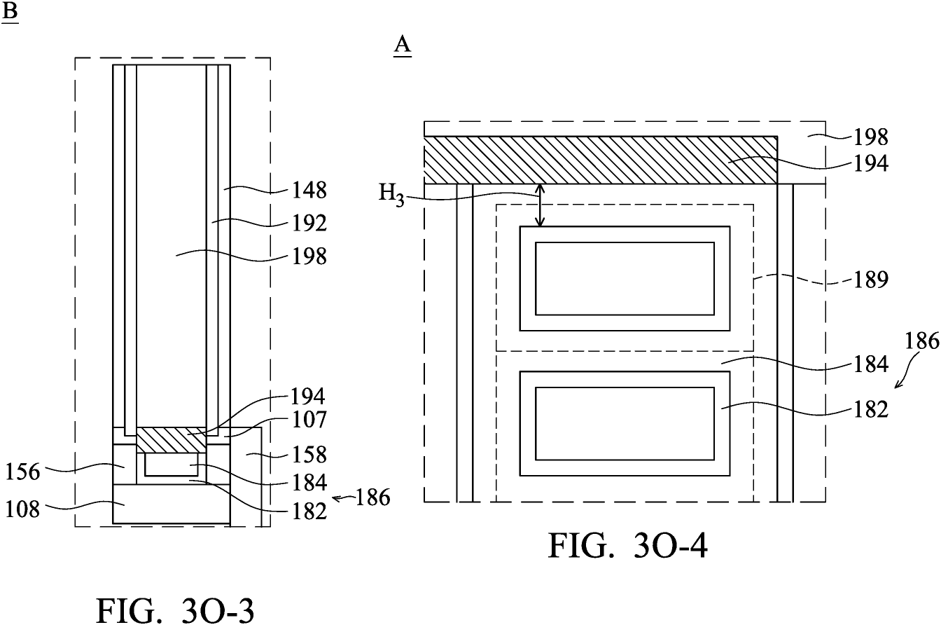

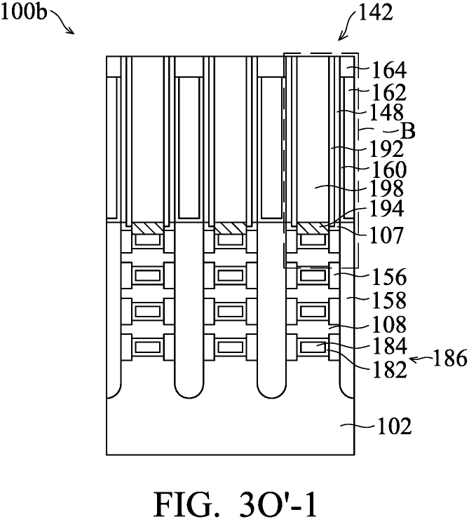

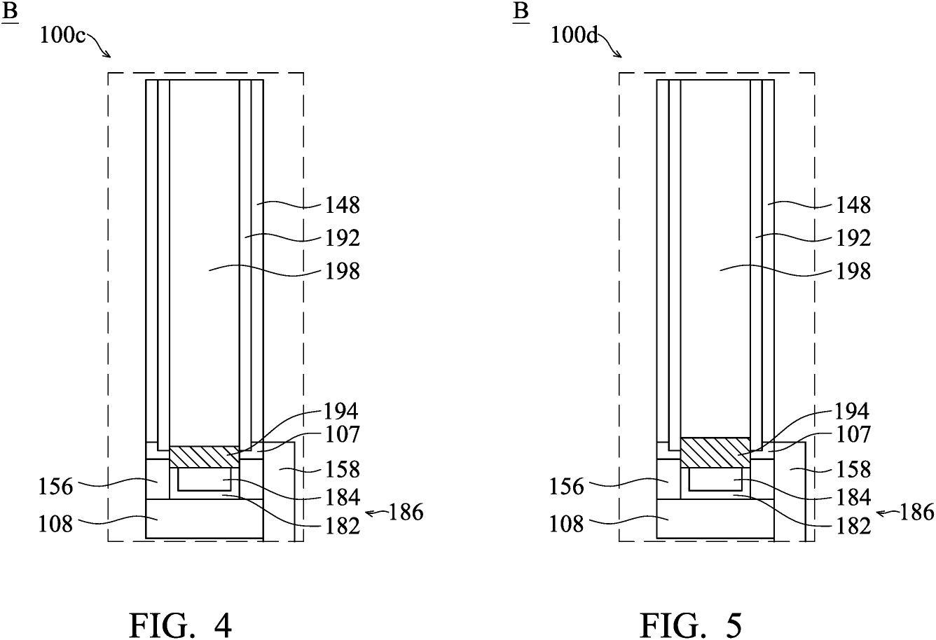

FIG. 3I-3 shows an enlarged cross-sectional representation of the region A in FIG. 3I-2, in accordance with some embodiments of the disclosure. FIGS. 3J-3 3L-1 3L-2 3L-3 3M-1 3M-2 3N-1 3N-2 3N-3 3O-1 3O-2 3O-3 show enlarged cross-sectional representation of the region B in FIGS. 3J-1 3J-2 3J-3 3L-1 3L-2 3L-3 3M-1 3M-2 3N-1 3N-2 3N-3 3O-1, in accordance with some embodiments of the disclosure. FIG. 3O-4 shows an enlarged cross-sectional representation of the region A in FIG. 3O-2, in accordance with some embodiments of the disclosure.

FIG. 3B'-1 shows a cross-sectional representation of forming the notches 154 of a semiconductor device structure 100b, in accordance with some embodiments of the disclosure. FIG. 3C'-1 shows a cross-sectional representation of forming the inner spacers 156 of the semiconductor device structure 100b, in accordance with some embodiments of the disclosure. FIG. 3O-1 shows a cross-sectional representation of forming a metal layer 194 of the semiconductor device structure 100b, in accordance with some embodiments of the disclosure.

As shown in FIG. 3A-1, the dummy gate structure 136 includes the dummy gate dielectric layer 138 and the dummy gate electrode layer 140, and the S/D recess 150 is formed, in accordance with some embodiments of the disclosure. More specifically, a portion of the hard mask layer 107, a portion of the first semiconductor layers 106 and a portion of the second semiconductor layers 108 are removed to form the S/D recesses 150. Note that the semiconductor device structure 100a in FIGS. 3A-1 3A-2 is similar to that in FIG. 2J, the difference between FIG. 3A-1 and FIG. 2J is that, three dummy gate structure 136 are shown in FIG. 3A-1, but two dummy gate structures 136 are shown in FIG. 2J. The number of the dummy gate structures 136 can be adjusted according to actual application.

As shown in FIG. 3A-2, the bottom surface of the S/D recess 150 is lower than the top surface of the isolation structure 116, in accordance with some embodiments of the disclosure.

Next, as shown in FIG. 3B-1, a portion of the first semiconductor layers 106 is removed to form a number of notches 154, in accordance with some embodiments of the disclosure.

FIG. 3B'-1 shows a cross-sectional representation of forming the notches 154 of a semiconductor device structure 100b, in accordance with some embodiments of the disclosure. FIG. 3B'-1 is similar to, FIG. 3B-1, the difference is that a portion of the second semiconductor layers 108 is removed in FIGS. 3B-1 3B-2, and therefore each of the second semiconductor layers 108 does not have rectangular shape (each of the second semiconductor layers 108 have rectangular shape in FIG. 3B-1). As a result, the side portions of the second semiconductor layers 108 are thinner than the middle portion of the second semiconductor layers 108.

FIG. 3B-2 is similar to, or the same as, FIG. 3A-2, in accordance with some embodiments of the disclosure.

Next, as shown in FIG. 3C-1, inner spacers 156 are formed in the notches 154, in accordance with some embodiments of the disclosure. The inner spacers 156 are configured to as a barrier between an S/D structure 158 (formed later, as shown in FIG. 3D-1) and a gate structure 186 (formed later, as shown in FIG. 3I-1). The inner spacers 156 can reduce the parasitic capacitance between the S/D structure 158 (formed later) and the gate structure 186 (formed later). The inner spacer material is firstly formed over the dummy gate structure 136 and the hard mask layers 142, and then a portion of the inner spacer material outside the notches 154 is removed to form the inner spacers 156.

FIG. 3C-2 is similar to, or the same as, FIG. 3B-2, in accordance with some embodiments of the disclosure.

FIG. 3C'-1 shows a cross-sectional representation of forming the inner spacers 156 of the semiconductor device structure 100b, in accordance with some embodiments of the disclosure. FIG. 3C'-1 is similar to, FIG. 3C-1, the difference is that height of each of the inner spacers 156 is greater than the height of each of the first semiconductor layers 106. More specifically, the bottom surface of the inner spacer layer 156 is lower than the bottom surface of the first semiconductor layer 106.

Next, as shown in FIG. 3D-1, S/D structures 158 are formed in the S/D recesses 150, in accordance with some embodiments of the disclosure. The hard mask layer 107 is in direct contact with the S/D structure 158. The top surface of the hard mask layer 107 is substantially level with the top surface of the S/D structure 158.

The S/D structure 158 may include silicon germanium (SiGe), indium arsenide (InAs), indium gallium arsenide (InGaAs), indium antimonide (InSb), gallium arsenide (GaAs), gallium antimonide (GaSb), indium aluminum phosphide (InAlP), indium phosphide (InP), or a combination thereof. The S/D structure 158 may dope with one or more dopants. In some embodiments, the S/D structure 158 is silicon (Si) doped with phosphorus (P), arsenic (As), antimony (Sb), or another applicable dopant. Alternatively, the S/D structure 158 is silicon germanium (SiGe) doped with boron (B) or another applicable dopant.

In some embodiments, the S/D structures 158 are formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes.

In some embodiments, when an N-type FET (NFET) device is desired, the S/D structures 158 include an epitaxially growing silicon (epi Si). Alternatively, when a P-type FET (PFET) device is desired, the S/D structures 158 include an epitaxially growing silicon germanium (SiGe).

As shown in FIG. 3D-2, the S/D structures 158 are formed in the S/D recesses 150, and one of the S/D structures 158 is between the two adjacent dielectric features 134. The top surface of the cap layer 126 is higher than the top surface of the S/D structure 158.

Afterwards, as shown in FIG. 3E-1, a contact etch stop layer (CESL) 160 is formed over the S/D structure 158, and an inter-layer dielectric (ILD) layer 162 is formed over the CESL 160, in accordance with some embodiments. Next, a portion of the ILD layer 162 is removed, and the oxide layer 144 and the nitride layer 146 are removed to expose the top surface of the dummy gate electrode layer 140. In some embodiments, the portion of the ILD layer 162 is removed by aplanarizing process, a chemical mechanical polishing (CMP) process.

After the planarizing process, the portion of ILD layer 162 and a portion of the CESL 160 are recessed to a level below the top surface of the dummy gate electrode layer 140 and a protection layer 164 is formed over the CESL 160 and the ILD layer 162 to protect the CESL 160 and the ILD layer 162 from being damaged by the subsequent etching process.

As shown in FIG. 3E-2, the CESL 160 is formed over the cap layer 126, the ILD layer 162 is formed over the CESL 160, and the protection layer 164 is formed over the ILD layer 162.

Afterwards, as shown in FIG. 3F-1, the dummy gate structure 136 is removed to form a trench 175, in accordance with some embodiments of the disclosure. More specifically, the dummy gate dielectric layer 138 and the dummy gate electrode layer 140 are removed to form the trench 175. As a result, the hard mask layer 107 is exposed by the trench 175.

FIG. 3F-2 shows the cross-sectional representation of the semiconductor device structure 100a along the dummy gate structure 136 along line Y₂-Y₂′ shown in FIG. 2J. As shown in FIG. 3F-2, the dummy gate dielectric layer 138 and the dummy gate electrode layer 140 are removed to form the trench 175. In addition, the cap layer 126 is exposed by the trench 175. As a result, the top surface of the hard mask layer 107 and the top surface of the cladding layer 118 are exposed by the trench 175.

Next, as shown in FIG. 3G-1, the first semiconductor layers 106 and the cladding layer 118 are removed to form a number of gaps 177, in accordance with some embodiments. As a result, a number of stacked nanostructures made of the second semiconductor layers 108 are obtained. A number of nanostructures (e.g. the second semiconductor layers 108) are stacked in the vertical direction. Note that the hard mask layer 107 is still over the topmost second semiconductor layer 108. The hard mask layer 107 is separated from the topmost second semiconductor layer 108 by the gap 177.

As shown in FIG. 3G-2, the liner layer 120 is exposed by the gaps 177 and the trench 175. There is a first width W₁ between sidewalls of two adjacent cap layers 126 along a horizontal direction.

Afterwards, as shown in FIGS. 3H-1 and 3H-2, a portion of the liner layer 120 and a portion of the cap layer 126 are removed by an etching process, in accordance with some embodiments. The etching process is used to increase the distance between the sidewall of the second semiconductor layers 108 and the sidewall of the filling layer 122. In addition, a portion of the hard mask layer 107 is also removed by the etching process. The etching process may be a multiple wet etching process or dry etching process. In some embodiments, the etching process is performed by using the etching gas including F-based (fluoride) gas.

The trench 175 and the gaps 177 are expanded by the etching process to increase the process window for forming the gate structure (formed later). In addition, the thickness of the hard mask layer 107 is decreased from the first thickness T₁ to the second thickness T₂ along a vertical direction. Therefore, the first thickness T₁ is greater than the second thickness T₂. There sidewalls of two adjacent cap layers 126 is also increased from the first width W₁ to the second width W₂ along a horizontal direction. Therefore, the second width W₂ is greater than the first width W_{1.} It should be noted that, a sidewall portion of the hard mask layer 107 directly below the first gate spacer 148 is not removed, and therefore the portion of the hard mask layer 107 still have the first thickness T₁. Therefore, the hard mask layer 107 has a U-shaped structure after the etching process.

Afterwards, as shown in FIGS. 3I-1 and 3I-2, a gate structure 186 is formed in the trench 175 and the gaps 177, in accordance with some embodiments. As a result, the number of nanostructures (e.g. the second semiconductor layers 108) are surrounded by the gate structure 186. The portion of the second semiconductor layers 108 covered by the gate structure 186 can be referred to as a channel region. The gate structure 186 includes a gate dielectric layer 182 and a gate electrode layer 184. The gate dielectric layer 182 is conformally formed along the main surfaces of the second semiconductor layers 108 to surround the second semiconductor layers 108. The inner spacers 156 are between the gate structure 186 and the S/D structures 158.

As shown in FIG. 3I-3, in some embodiments, when the gate electrode layer 184 is formed in the gaps 177, a portion of the gate electrode layer 184 is formed upwardly from the top surface of the topmost second semiconductor layer 108 to close to the bottom surface of the hard mask layer 107. In addition, another portion of the gate electrode layer 184 is formed downwardly from the bottom surface of the hard mask layer 107 to close to the top surface of the topmost second semiconductor layer 108. When the gate electrode layer 184 is formed form two sides, there is an merge seam 189 (shown in the dot line) between the topmost second semiconductor layer 108 and the hard mask layer 107. The merge seam 189 also exists in the following figures, but is omitted for clarity. Although the second gate electrode layer 184 is made of the same material, the merge seam 189 is seen from a microscope view or microscope image.

In some embodiments, the gate dielectric layer 182 includes a high-k dielectric layer. In some embodiments, the high-k gate dielectric layer is made of one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the high-k gate dielectric layer is formed using chemical vapor deposition (CVD), atomic layer deposition (ALD), another suitable method, or a combination thereof.

In some embodiments, the gate electrode layer 184 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof.

In addition, the gate electrode layer 184 includes one or more layers of n-work function layer or p-work function layer. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

Next, as shown in FIGS. 3J-1 and 3J-2, a portion of the gate structure 186 is removed to expose the top surface of the hard mask layer 107, in accordance with some embodiments. In addition, the cap layer 126 is also removed, as shown in FIG. 3J-2.

As shown in FIGS. 3J-1 and 3J-3, the portion of the gate dielectric layer 182 and the portion of the gate electrode layer 184 which are above the hard mask layer 107 are removed by an etching process. As a result, a trench 191 is formed to expose the first gate spacer 148.

It should be noted that, the nanostructures (the second semiconductor layers 108) which are directly below the hard mask layer 107 are protected by the hard mask layer 107 from being damaged by the etching process. If no hard mask layer is above the nanostructures (the second semiconductor layers 108), the topmost nanostructure (the topmost second semiconductor layer 108) may be etched by the etching process. Therefore, the hard mask layer 107 provides a protection function.

Next, as shown in FIGS. 3K-1 and 3K-2, a second gate spacer 192 is formed adjacent to the first gate spacer 148, in accordance with some embodiments of the disclosure. As shown in FIGS. 3K-1 3K–2, the bottom surface of the second gate spacer 192 is lower than the bottom surface of the first gate spacer 148.

The inner spacer layer 156 has a third thickness T₃ along the horizontal direction. The first gate spacer 148 has a fourth thickness T₄ along the horizontal direction, and the second gate spacer 192 has a fifth thickness T₅ along the horizontal direction. In some embodiments, the fourth thickness T₄ of the first gate spacer 148 is in a range from about 1 nm to about 10 nm. In some embodiments, a ratio of the fourth thickness T₄ of the first gate spacer 148 to the third thickness T₃ is in a range from about 30% to about 80%. In some embodiments, the third thickness T₃ of the inner spacer layer 156 is equal to the sum of the fourth thickness T₄ of the first gate spacer 148 and the fifth thickness T₅ of the second gate spacer 192. In some embodiments, the total of the fourth thickness T₄ of the first gate spacer 148 and the fifth thickness T₅ of the second gate spacer 192 is in a range from about 80% to about 150 % of the third thickness T₃ of the inner spacer layer 156 to avoid reliability issue. In some other embodiments, no second gate spacer is formed when the ratio of the fourth thickness T₄ of the first gate spacer 148 to the third thickness T₃ is in a range from about 80% to about 150 %. In other words, when the first gate spacer 148 is thick enough, no second gate spacer is formed on the first gate spacer 148.

Afterwards, as shown in FIGS. 3L-1 and 3L-2, a portion of the hard mask layer 107 is removed, and a portion of the gate dielectric layer 182 is removed, in accordance with some embodiments of the disclosure. As shown in FIGS. 3L-1 and 3L-3, the topmost surface of the gate electrode layer 184 is exposed by the trench 191.

Afterwards, as shown in FIGS. 3M-1 and 3M-2, a metal layer 194 is formed over the exposed gate electrode layer 184, in accordance with some embodiments of the disclosure. As shown in FIGS. 3M-1 and 3M-3, the metal layer 194 is formed over the gate electrode layer 184 and the filling layer 122. The metal layer 194 is in direct contact with the gate electrode layer 184 of the gate structure 186 and the second gate spacer 192. In addition, the meta layer 194 is in direct contact with the hard mask layer 107. A portion of the second gate spacer 192 is below the top surface of the metal layer 194. The top surface of the metal layer 194 is substantially level with the top surface of the S/D structure 158. In addition, the top surface of the metal layer 194 is substantially level with the bottom surface of the first gate spacer 148.

In some embodiments, the metal layer 194 is made of Ru, W, TiN, TaN, Co, Ti, TiAl, or the like. In some embodiments, the metal layer 194 includes two metal-containing material layers, such as the bottom layer (e.g. a TiN layer) and the main layer (e.g. a W layer) formed over the bottom layer. The metal layer 194 may be configured to electrically connect various portions of the gate structures 186 divided by the dielectric features 134-1, 134-2, and 134-3. In some embodiments, the metal layer 194 has a second height H₂ along a vertical direction in a range from about 1 nm to about 10 nm, such as about 2 nm to about 6 nm. The metal layer 194 should be thick enough or it may be broken in subsequent manufacturing processes and the connection between different portions of the gate structures 186 may be affected. On the other hand, the metal layer 194 should not be too thick or the capacitance of the resulting device may be increased and the speed of the resulting device may be reduced.

Afterwards, as shown in FIGS. 3N-1, 3N-2 and 3N-3, a photoresist structure 196 is formed over the metal layer 194, and the photoresist structure 196 is patterned to form an opening 197, in accordance with some embodiments of the disclosure. Next, the metal layer 194 is patterned by using the photoresist structure 196 as the mask. The middle portion of the metal layer 194 is removed by the etching process.

Afterwards, as shown in FIGS. 3O-1 and 3O-2, the photoresist structure 196 is removed, and a dielectric layer 198 is formed into the opening 197 and over the metal layer 194, in accordance with some embodiments of the disclosure. FIG. 3O-3shows an enlarged cross-sectional representation of the region B in FIG. 3O-1, in accordance with some embodiments of the disclosure.

As shown in FIGS. 3O-1, 3O-2 and 3O-3, the hard mask layer 107 is formed over and in direct contact with the inner spacer layer 156. In addition, the hard mask layer 107 is between the gate structure 186 and the S/D structure 158. The hard mask layer 107 is between the inner spacer layer 156 and the first gate spacer 148. The hard mask layer 107 is below the first gate spacer 148 and the second gate spacer 192. In addition, the hard mask layer 107 is in direct contact with the first gate spacer 148 and the second gate spacer 192.

The top surface of the inner spacer layer 156 is higher than the topmost nanostructure (e.g. the topmost second semiconductor layer 108). The inner sidewall of the inner spacer layer 156 is substantially aligned with the outer sidewall of the metal layer 194. The metal layer 194 is in direct contact with the second gate spacer 192 and the hard mask layer 107. In addition, the metal layer is separated from the first gate spacer 148 by the second gate spacer 192.

In some embodiments, the dielectric layer 198 may include multilayers made of multiple dielectric materials, such as Al₂O₃, ZrO₂, silicon oxide, silicon nitride, silicon oxynitride, phosphosilicate glass (PSG), borophosphosilicate glass (BPSG), or other applicable dielectric materials. The dielectric layer 190 may be formed by chemical vapor deposition (CVD), physical vapor deposition, (PVD), atomic layer deposition (ALD), or other applicable processes.

As shown in FIG. 3O-4, the gate electrode layer 184 has a third height H₃ along a vertical direction. In some embodiments, the third height H₃ is in a range from about 2 nm to about 15 nm. The merge seam 189 exists in two adjacent second semiconductor layers 108.

It should be noted that the hard mask layer 107 provides protection, and therefore when the top portion of the gate structure 186 above the hard mask layer 107 is removed, the topmost nanostructure (e.g. second semiconductor layer 108) below the hard mask layer 107 is protected by the hard mask layer 107 and is not damaged.

FIG. 3O-1 shows a cross-sectional representation of forming the metal layer 194 of the semiconductor device structure 100b, in accordance with some embodiments of the disclosure. FIG. 3O-1 is similar to, FIG. 3O-1, the difference is that a portion of the second semiconductor layers 108 is removed in FIG. 3O-1, and therefore each of the second semiconductor layers 108 does not have rectangular shape. The bottommost surface of the inner spacer layer 156 is lower than the bottommost surface of the gate dielectric layer 182.

FIG. 4 shows a cross-sectional representation of a semiconductor device structure 100c, in accordance with some embodiments. The semiconductor structure 100c of FIG. 4 is similar to, or the same as, the semiconductor structure 100a of FIG. 3O-1, the difference between the FIG. 4 and FIG. 3O-1 is that, the top surface of the metal layer 194 is lower than the top surface of the S/D structure 158 in FIG. 4. In addition, the top surface of the metal layer 194 is lower than the top surface of the hard mask layer 107. The top surface of the metal layer 194 is still higher than the bottom surface of the second gate spacer 192.

FIG. 5 shows a cross-sectional representation of a semiconductor device structure 100d, in accordance with some embodiments. The semiconductor structure 100d of FIG. 5 is similar to, or the same as, the semiconductor structure 100a of FIG. 3O-1, the difference between the FIG. 5 and FIG. 3O-1 is that, the top surface of the metal layer 194 is higher than the top surface of the S/D structure 158 in FIG. 5. In addition, the top surface of the metal layer 194 is higher than the top surface of the hard mask layer 107.

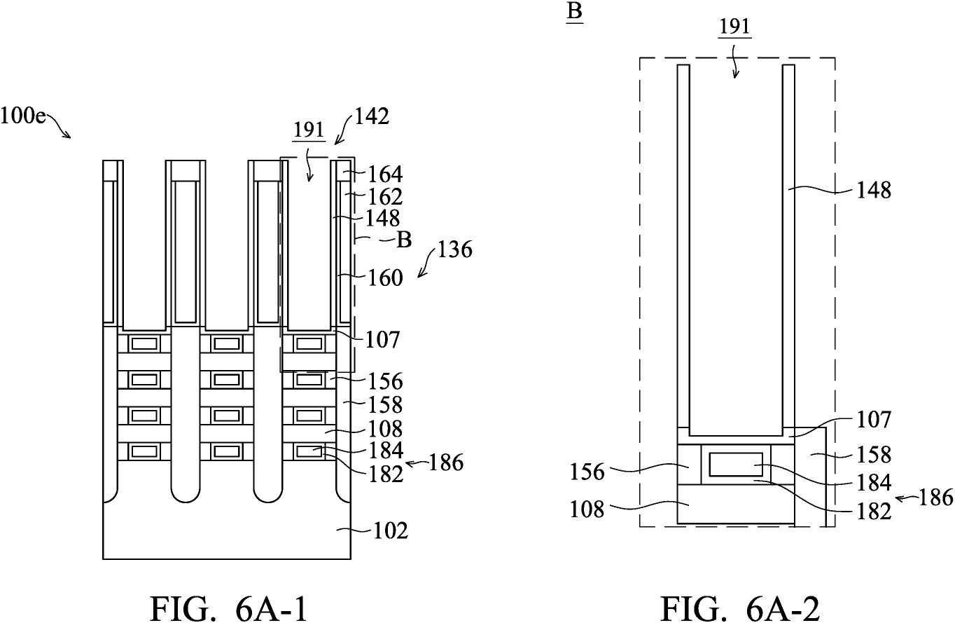

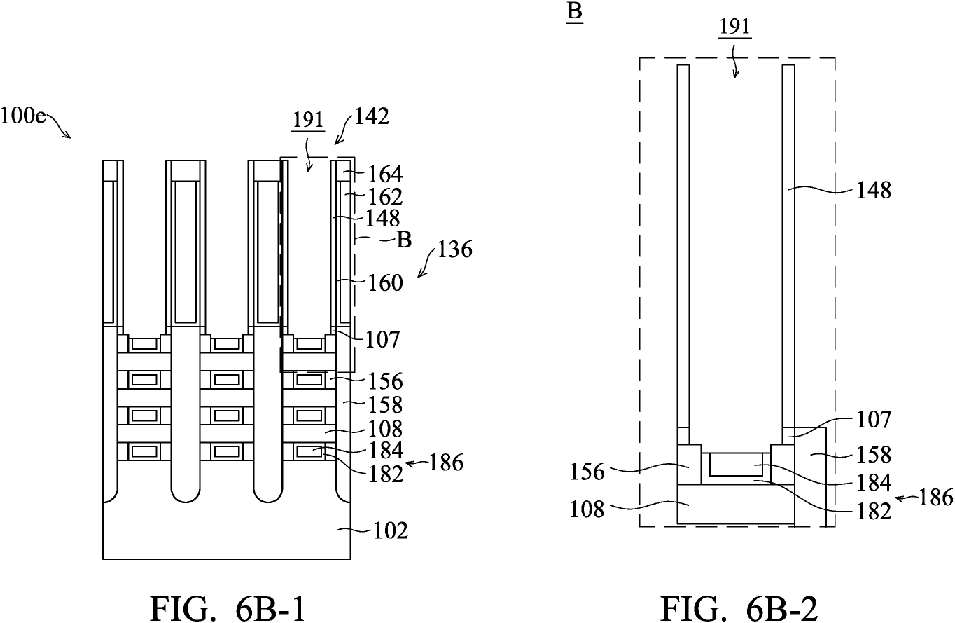

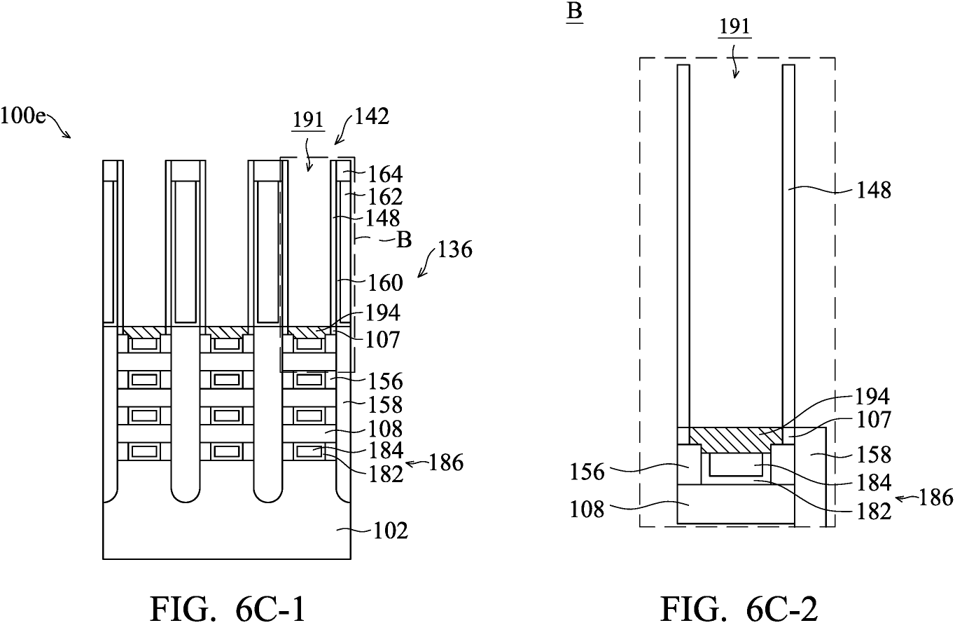

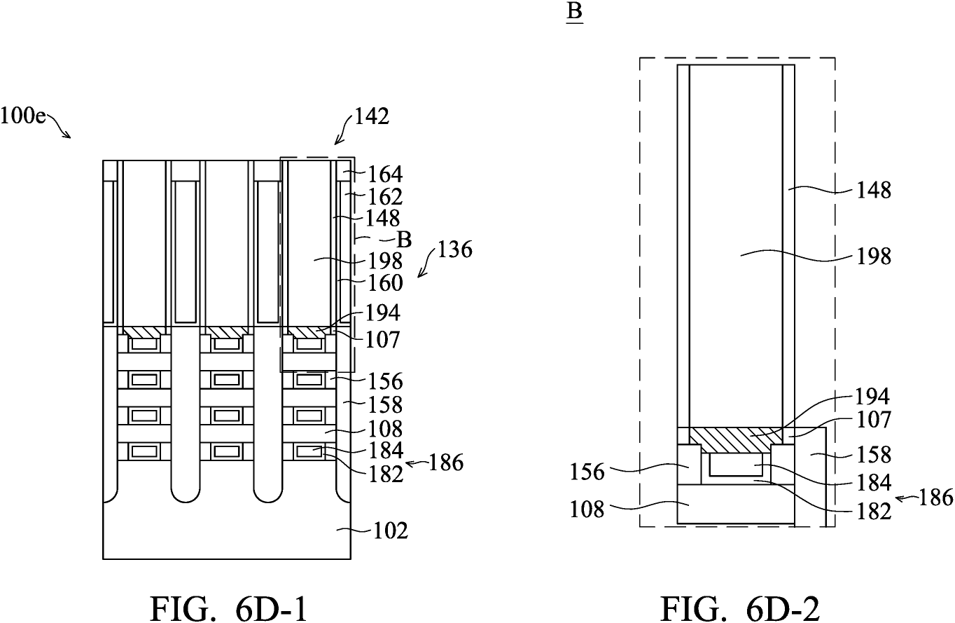

FIGS. 6A-1 6A-2 6B-1 6B-2 6C-1 6C-2 6D-1 show cross-sectional representations of various stages of forming the semiconductor device structure along line X-X′ shown in FIG. 2J, in accordance with some embodiments of the disclosure. FIGS. 6A-2 6B-1 6B-2 6C-1 6C-2 6D-1 6D-2 show enlarged cross-sectional representation of the region B in FIGS. 6A-1 6A-2 6B-1 6B-2 6C-1 6C-2 6D-1, in accordance with some embodiments of the disclosure. In the semiconductor device structure 100e, no second gate spacer is formed over the first gate spacer 148.

As shown in FIGS. 6A-1 and 6A-2, the semiconductor device structure 100e is similar to, or the same as, the semiconductor structure 100a of FIG. 3J-1. More specifically, the portion of the gate dielectric layer 182 and the portion of the gate electrode layer 184 which are above the hard mask layer 107 are removed by an etching process. As a result, a trench 191 is formed to expose the first gate spacer 148.

Next, as shown in FIGS. 6B-1 and 6B-2, a portion of the hard mask layer 107 and a portion of the gate dielectric layer 182 are removed to expose the gate electrode layer 184, in accordance with some embodiments of the disclosure. The hard mask layer 107 is directly below the first gate spacer 148.

Afterwards, as shown in FIGS. 6C-1 and 6C-2, the metal layer 194 is formed over the gate electrode layer 184, in accordance with some embodiments of the disclosure. The metal layer 194 has a T-shaped structure, and the hard mask layer 107 has a rectangular structure. The expending portion of the T-shaped structure is formed over the inner spacer layer 156. The bottom portion of the T-shaped structure is formed over the gate dielectric layer 182 and the gate electrode layer 184.

As shown in FIGS. 6D-1 and 6D-2, the dielectric layer 198 is formed over the metal layer 194. The metal layer 194 is in direct contact with the hard mask layer 107, and the hard mask layer 107 is between the metal layer 194 and the S/D structure 158. In addition, the hard mask layer 107 is between the inner spacer 156 and the first gate spacer 148.

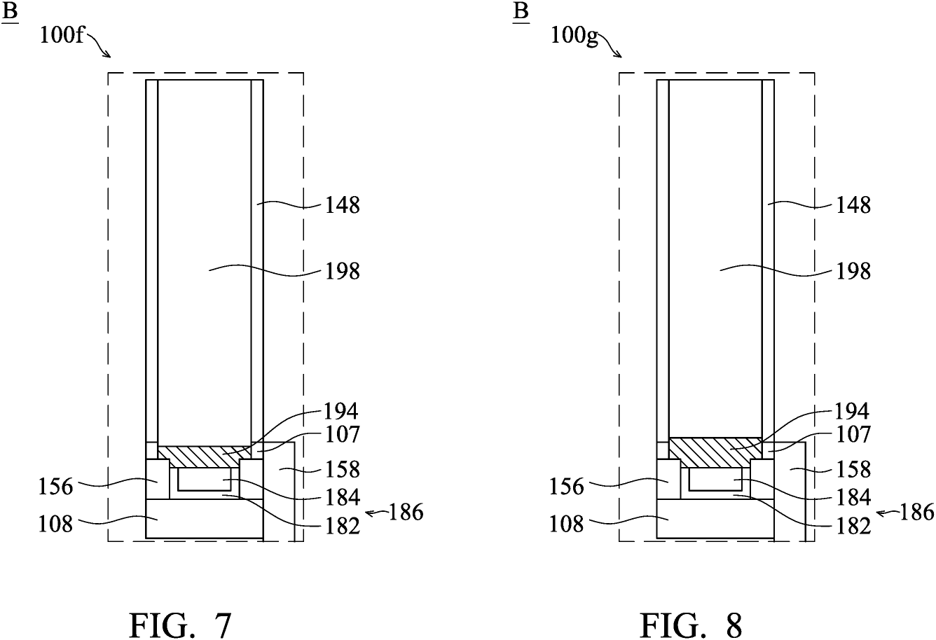

FIG. 7 shows a cross-sectional representation of a semiconductor device structure 100f, in accordance with some embodiments. The semiconductor structure 100f of FIG. 7 is similar to, or the same as, the semiconductor structure 100e of FIG. 6C-1, the difference between the FIG. 7 and FIG. 6C-1 is that, the top surface of the metal layer 194 is lower than the top surface of the S/D structure 158 in FIG. 7. In addition, the top surface of the metal layer 194 is lower than the top surface of the hard mask layer 107.

FIG. 8 shows a cross-sectional representation of a semiconductor device structure 100g, in accordance with some embodiments. The semiconductor structure 100g of FIG. 8 is similar to, or the same as, the semiconductor structure 100e of FIG. 6C-1, the difference between the FIG. 8 and FIG. 6C-1 is that, the top surface of the metal layer 194 is higher than the top surface of the S/D structure 158 in FIG. 8. In addition, the top surface of the metal layer 194 is higher than the top surface of the hard mask layer 107.

In some embodiments, when the second gate spacer 192 is formed on the first gate spacer 148, the hard mask layer 107 has a L-shaped structure. When the hard mask layer 107 has the L-shaped structure, the hard mask layer 107 is in direct contact with the first gate spacer 148 and the second gate spacer 192. The bottom surface of the second spacer 192 is lower than the top surface of the hard mask layer 107. In addition, the bottom surface of the second gate spacer 192 is lower than an interface between the hard mask layer 107 and the first gate spacer 148.

In some other embodiments, when no second gate spacer is formed on the first gate spacer 148, the hard mask layer 107 has a rectangular structure. When hard mask layer 107 has the rectangular structure, the hard mask layer 107 is in direct contact with the first gate spacer layer 148. The metal layer 194 has a T-shaped structure.

Embodiments for forming a semiconductor device structure and method for formation the same are provided. A plurality of nanostructures formed over a substrate. A gate structure surrounds the first nanostructures, and an S/D structure adjacent to the gate structure. An inner spacer layer is formed between the gate structure and the S/D structure. A hard mask layer is formed over the inner spacer. The hard mask layer is between the gate structure and the S/D structure, and it is between the inner spacer layer and a gate spacer. The hard mask layer is used to protect the underlying layers. The hard mask layer protects the topmost nanostructure from being damaged when the top portion of the gate structure above the hard mask layer is removed. Therefore, the performance of semiconductor device structure is improved.

In some embodiments, a semiconductor device structure is provided. The semiconductor device structure includes a plurality of first nanostructures stacked over a substrate in a vertical direction. The semiconductor device structure includes a gate structure surrounding the first nanostructures, and an S/D structure adjacent to the gate structure. The semiconductor device structure also includes an inner spacer layer formed between the gate structure and the S/D structure, and a hard mask layer formed over the inner spacer layer. The hard mask layer is between the gate structure and the S/D structure, and is in direct contact with the inner spacer layer.

In some embodiments, a semiconductor device structure is provided. The semiconductor device structure includes a plurality of first nanostructures formed over a substrate. The semiconductor device structure includes a gate structure surrounding the first nanostructures, and a metal layer formed over the gate structure. The semiconductor device structure includes a hard mask layer adjacent to the metal layer, and a first gate spacer formed over the hard mask layer. The first gate spacer is in direct contact with the hard mask layer.

In some embodiments, a method for forming a semiconductor device structure is provided. The method includes forming a first fin structure over a substrate, and the first fin structure includes a plurality of first semiconductor layers and a plurality of second semiconductor layers stacked in a vertical direction. The method includes forming a hard mask layer over the first fin structure, and forming a dummy gate structure over the hard mask layer. The method also includes forming a dielectric layer over the dummy gate structure, and removing the dummy gate structure to form a trench. The method includes removing the first semiconductor layers to form a gap, and forming a gate structure in the trench and the gap. The method further includes removing a portion of the gate structure to expose a portion of the hard mask layer, and removing the portion of the hard mask layer to expose the gate structure to form a recess and the remaining hard mask layer. The method further includes forming a metal layer in the recess, and the metal layer is in direct contact with the remaining hard mask layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
a plurality of first nanostructures stacked over a substrate in a vertical direction;
a gate structure surrounding the first nanostructures;
an S/D structure adjacent to the gate structure;
an inner spacer layer formed between the gate structure and the S/D structure; and
a hard mask layer formed over the inner spacer layer, wherein the hard mask layer is between the gate structure and the S/D structure and in direct contact with the inner spacer layer.

2. The semiconductor device structure as claimed in claim 1, further comprising:
a gate spacer formed adjacent to the gate structure, wherein the hard mask layer is below the gate spacer and in direct contact with the gate spacer.

3. The semiconductor device structure as claimed in claim 1, further comprising:
a metal layer formed over the gate structure, wherein the metal layer is in direct contact with the gate structure.

4. The semiconductor device structure as claimed in claim 3, further comprising:
a gate spacer formed adjacent to the gate structure, wherein a portion of the gate spacer is below a top surface of the metal layer.

5. The semiconductor device structure as claimed in claim 1, wherein a top surface of the inner spacer layer is higher than a topmost first nanostructure.

6. The semiconductor device structure as claimed in claim 1, wherein an inner sidewall of the inner spacer layer is substantially aligned with an outer sidewall of the hard mask layer.

7. The semiconductor device structure as claimed in claim 1, further comprising:
a first gate spacer formed adjacent to the gate structure; and
a second gate spacer formed adjacent to the first gate spacer, wherein a bottom surface of the second gate spacer is lower than a bottom surface of the first gate spacer.

8. The semiconductor device structure as claimed in claim 1, further comprising:
a plurality of second nanostructures stacked adjacent to the first nanostructures in a vertical direction; and
a dielectric feature between the first nanostructures and the second nanostructures, wherein the dielectric feature comprises a liner layer and a filling layer over the liner layer.

9. The semiconductor device structure as claimed in claim 1, wherein the hard mask layer is in direct contact with the S/D structure.

10. A semiconductor device structure, comprising:
a plurality of first nanostructures over a substrate;
a gate structure surrounding the first nanostructures;
a metal layer formed over the gate structure;
a hard mask layer adjacent to the metal layer; and
a first gate spacer formed over the hard mask layer, wherein the first gate spacer is in direct contact with the hard mask layer.

11. The semiconductor device structure as claimed in claim 10, further comprising:
an S/D structure formed adjacent to the gate structure, wherein the S/D structure is in direct contact with the hard mask layer.

12. The semiconductor device structure as claimed in claim 11, further comprising:
an inner spacer layer formed between the gate structure and the S/D structure, wherein the hard mask layer is between the inner spacer layer and the first gate spacer.

13. The semiconductor device structure as claimed in claim 10, further comprising:
a second gate spacer adjacent to the first gate spacer, wherein the second gate spacer is in direct contact with the hard mask layer.

14. The semiconductor device structure as claimed in claim 13, wherein a bottom surface of the second gate spacer is lower than a bottom surface of the first gate spacer.

15. The semiconductor device structure as claimed in claim 10, wherein a top surface of the metal layer is higher than or lower than a top surface of the hard mask layer.

16. A method for forming a semiconductor device structure, comprising:
forming a first fin structure over a substrate, wherein the first fin structure comprises a plurality of first semiconductor layers and a plurality of second semiconductor layers stacked in a vertical direction;
forming a hard mask layer over the first fin structure;
forming a dummy gate structure over the hard mask layer;
forming a dielectric layer over the dummy gate structure;
removing the dummy gate structure to form a trench;
removing the first semiconductor layers to form a gap;
forming a gate structure in the trench and the gap;
removing a portion of the gate structure to expose a portion of the hard mask layer;
removing the portion of the hard mask layer to expose the gate structure to form a recess and a remaining hard mask layer; and
forming a metal layer in the recess, wherein the metal layer is in direct contact with the remaining hard mask layer.

17. The method for forming the semiconductor device structure as claimed in claim 16, further comprising:
forming a gate spacer adjacent to the gate structure, wherein the gate spacer is formed over the hard mask layer.

18. The method for forming the semiconductor device structure as claimed in claim 16, further comprising:
removing a portion of the first semiconductor layer to form a recess; and
forming an inner spacer layer in the recess, wherein the inner spacer layer is in direct contact with the hard mask layer.

19. The method for forming the semiconductor device structure as claimed in claim 16, further comprising:
forming a second fin structure adjacent to the first fin structure; and
forming a dielectric feature between the first fin structure and the second fin structure, wherein the dielectric feature comprises a liner layer and a filling layer over the liner layer.

20. The method for forming the semiconductor device structure as claimed in claim 19, further comprising:
removing a portion of the liner layer before forming the gate structure.
